(19) United States
(12) Patent Application Publication
(10) Pub. No.: US 2026/0313862 A1
(43) Pub. Date: Oct. 8, 2026

(54) CONTACTING ARRANGEMENT, PROTECTIVE ELEMENT AND PROTECTIVE ARRANGEMENT

(71) Applicant: ElringKlinger AG, Dettingen (DE)

(72) Inventors: Fabian Albrecht, Dettingen (DE); Eugen Kübler, Dettingen (DE); Armin Ehni, Dettingen (DE); Johannes Haener, Dettingen (DE); Fabian Vesenmaier, Dettingen (DE)

(73) Assignee: ElringKlinger AG, Dettingen (DE)

(21) Appl. No.: 19/634,508

(22) Filed: Mar. 31, 2026

(30) Foreign Application Priority Data
Apr. 4, 2025 (DE) 10 2025 113 424.3

(51) Int. Cl. H05K 9/00; F16J 15/02

(52) U.S. Cl. CPC H05K 9/0015; F16J 15/022; H05K 9/0081

(57) ABSTRACT

A contacting arrangement for electrically contacting a protective element for increasing electromagnetic compatibility, wherein the contacting arrangement has a contacting zone.

### RELATED APPLICATION

This application claims the benefit of German application No. 10 2025 113 424.3 filed on Apr. 4, 2025, which is incorporated herein by reference in its entirety and for all purposes.

### FIELD OF DISCLOSURE

The present invention relates to the technical field of protective elements for increasing electromagnetic compatibility.

### BACKGROUND

Electromagnetic compatibility (EMC) refers to non-interference between electrical or electronic appliances and their surroundings.

Modern motor vehicles are at least partially electrically powered. For this purpose, said motor vehicles have installed therein not only high-power electrochemical energy storage devices but also, inter alia, inverters and electric motors which serve for the propulsion or acceleration of the motor vehicle. The various components are interconnected via electrical cables.

By means of an inverter, the direct current provided by the electrochemical energy storage device can be converted into alternating current. Inverters are also referred to as power inverters.

Consequently, modern motor vehicles comprise strong sources of electrical, magnetic or electromagnetic fields.

Furthermore, ever-increasing numbers of devices which communicate via electrical, magnetic or electromagnetic signals or electromagnetic waves are being integrated into motor vehicles or used in motor vehicles by vehicle occupants.

Ensuring EMC is thus a growing challenge. It is sought to make this possible with the lowest possible component weights, such that the weight of the motor vehicle is as far as possible not increased or is increased only to a small extent.

To shield a source of electromagnetic radiation, use may be made of a protective arrangement for increasing electromagnetic compatibility. The protective arrangement may have at least two protective elements which fully or partially enclose an interior space of the protective arrangement. The protective arrangement may be a housing, wherein the protective elements may be components of the housing. The protective elements may be delimiting elements which delimit the interior space with respect to a surrounding exterior space.

The entire source of electromagnetic radiation, or a part or portion of the source of electromagnetic radiation, may be arranged in the interior space of the protective arrangement. Alternatively, a device which is sensitive to electromagnetic radiation, or a part or portion of a device which is sensitive to electromagnetic radiation, may be arranged in the interior space of the protective arrangement in order to enable it to be shielded with respect to a source of electromagnetic radiation which is situated outside the interior space.

The document WO 2024/231253 A2 describes a contacting element by which electrical contact is produced between a contacting zone of a protective element and a device. It is described that the contacting element may be arranged on a carrier, wherein the carrier may be deformable and/or elastic. The contacting element may contain or be produced from an electrically conductive material, wherein the electrically conductive material may contain aluminum. The contacting element may extend from a protective element side of the carrier to a device side of the carrier. The carrier may contain an elastic seal material and/or be produced from an elastic seal material. The elastic seal material may contain or consist of a natural or synthetic rubber, for example an ethylene propylene diene monomer, a silicone rubber and/or a fluororubber, a polyurethane and/or an ethylene tetrafluoroethylene.

### SUMMARY OF THE INVENTION

The present invention is based on the object of providing, with little outlay, a contacting arrangement, a protective element and/or a protective arrangement with which electromagnetic compatibility can be effectively increased.

The object is achieved according to the invention by means of the contacting arrangement according to the independent claim directed thereto.

The contacting arrangement is a contacting arrangement for electrically contacting a protective element for increasing electromagnetic compatibility.

The contacting arrangement may advantageously be suitable for electrically contacting a protective element.

The protective element may advantageously be suitable for increasing electromagnetic compatibility.

For example, the protective element for increasing electromagnetic compatibility may be an element for shielding electromagnetic radiation.

It may be advantageous if the contacting arrangement has a contacting zone, wherein it may be advantageous if the contacting zone can be placed in electrical contact with a component against which the contacting arrangement can come to lie.

It may be particularly advantageous if the contacting arrangement is a contacting arrangement of a protective element described herein. For example, it may be the case that, when the protective element is attached to a component, the contacting zone can be placed in electrical contact with the component such that an electrical connection via the contacting zone can be produced from a shielding layer of the protective element via the contacting arrangement to the component.

It may be advantageous if the contacting arrangement has a contacting protrusion.

It may be advantageous if the contacting arrangement has the contacting zone on the contacting protrusion.

For example, the contacting arrangement may have a contacting protrusion, wherein the contacting arrangement has the contacting zone on the contacting protrusion.

It may be advantageous if the contacting zone is a first contacting zone, and the contacting arrangement has a second contacting zone, wherein the first contacting zone is electrically conductively connected to the second contacting zone.

It may be particularly advantageous if the contacting arrangement is a contacting arrangement of a protective element described herein, the second contacting zone is in electrical contact with the shielding layer, and the electrical connection that can be produced from the shielding layer of the protective element to the component is a connection which leads via the electrical contact of the first contacting zone with the component and via the electrical contact of the second contacting zone with the shielding layer.

It may be advantageous if the contacting arrangement has a first surface region.

It may be advantageous if the contacting arrangement has a second surface region.

It may be advantageous if the contacting arrangement has an apical surface region.

It may be advantageous if the contacting arrangement has a basal surface region.

It may be advantageous if the contacting arrangement has a first surface region and a second surface region.

It may be advantageous if the contacting arrangement has an apical surface region and a basal surface region.

It may be advantageous if the first surface region is the apical surface region.

It may be advantageous if the second surface region is the basal surface region.

It may be advantageous if the first contacting zone is formed on the first surface region.

It may be advantageous if the second contacting zone is formed on the second surface region.

It may be particularly advantageous if the first contacting zone is formed on the first surface region and the second contacting zone is formed on the second surface region.

It may be advantageous if the first contacting zone is formed on the apical surface region.

It may be advantageous if the second contacting zone is formed on the basal surface region.

It may be particularly advantageous if the first contacting zone is formed on the apical surface region and the second contacting zone is formed on the basal surface region.

It may be advantageous if the first contacting zone and the second contacting zone are connected by means of an electrically conductive material.

It may be advantageous if the electrically conductive material is a metallic material.

The metallic material may for example contain aluminum.

The electrically conductive material may for example be or have a metallic foil, a metallic lattice, a metallic mesh or a metallic fabric, in particular an aluminum foil, an aluminum lattice, an aluminum mesh or an aluminum fabric, wherein the aluminum foil, the aluminum lattice, the aluminum mesh or the aluminum fabric may contain aluminum preferably in the form of an alloy which contains at least 50 wt.% Al, preferably at least 60 wt.% Al, for example at least 85 wt.% Al.

For example, the electrically conductive material may be a sheet material, in particular a sheet aluminum material, for example an aluminum foil.

It may be advantageous if the first surface region and the second surface region are mutually spaced surface portions of the electrically conductive material.

It may be advantageous if the apical surface region and the basal surface region are mutually spaced surface portions of the electrically conductive material.

It may be advantageous if the contacting arrangement has the electrically conductive material, in particular the electrically conductive material by means of which the first contacting zone and the second contacting zone are connected.

It may be advantageous if the contacting arrangement has a main body.

It may be advantageous if the contacting arrangement has a plastics material.

It may be advantageous if the contacting arrangement has a main body, wherein it may be advantageous if the contacting arrangement has a plastics material.

It may be advantageous if the plastics material extends into the main body and into the contacting protrusion, and/or the main body and the contacting protrusion are constructed entirely or partially from the plastics material.

It may be advantageous if the plastics material contains a polymer or a mixture of different polymers. The plastics material may preferably contain an additive or a plurality of additives. Additives are in particular reinforcing materials, filler materials, flame retardants, colorants, heat stabilizers, light stabilizers, antioxidants, stabilizers, plasticizers, blowing agents, lubricants, antistatic agents and impact modifiers.

It may be particularly advantageous if the plastics material contains no blowing agents.

The polymer or the mixture of different polymers may form a matrix. The single additive or the plurality of additives may be dispersed in the matrix.

It may be advantageous if the contacting protrusion projects out of the main body.

It may be advantageous if, in a cross section of the contacting arrangement, the main body is substantially triangular, quadrangular, preferably substantially rectangular.

It may be advantageous if, in the cross section of the contacting arrangement, the apical surface region is convex and/or forms a corner or tip, wherein the corner or tip may optionally be rounded.

It may be advantageous if, in the cross section of the contacting arrangement, the basal surface region is flat and/or less convex than the apical surface region and/or more heavily rounded than the corner or tip.

The cross section may in particular be a cross section oriented orthogonally to a main extent direction of the contacting arrangement.

The main extent direction of the contacting arrangement may be identical over the entire length or over almost the entire length of the contacting arrangement. This is true in particular if the contacting arrangement extends in a straight manner from one end of the contacting arrangement to another end of the contacting arrangement.

In general, the main extent direction of the contacting arrangement can be understood here to mean a local main extent direction at that point of the cross section at which the cross section intersects the contacting arrangement. The main extent direction may, in a cross section, extend along a path which runs through the center of area of said cross section and through the centers of area of the cross sections immediately adjacent to the cross section.

The main body can be considered to be substantially triangular, quadrangular or rectangular in the cross section in particular if the main body can be approximated in the cross section by a triangle, by a quadrangle or by a rectangle.

In particular, if it can be approximated by a triangle, by a quadrangle or by a rectangle, the main body may, in the cross section, fill at least 85 %, preferably at least 90 %, of the area of a smallest triangle, quadrangle or rectangle in which the main body can be entirely accommodated in the cross section.

It may be advantageous if the plastics material is an elastomer material. The elastomer material may for example be a thermoplastic elastomer material.

It is known that thermoplastic elastomers are plastics materials which behave similarly to classic elastomers at room temperature but which, when heat is supplied, can be plastically deformed and thus exhibit thermoplastic behavior.

If the plastics material is a thermoplastic elastomer material, it contains, in particular, a polymer formed among thermoplastic elastomers, or a mixture of different polymers which contain a thermoplastic elastomer.

In the case of thermoplastic elastomers, it is possible in particular for elastic polymer chains to be incorporated into thermoplastic material. They can be processed in a purely physical process by a combination of high shear forces, application of heat and subsequent cooling.

If the plastics material is a thermoplastic elastomer material, it contains, in particular, a polymer selected from among thermoplastic elastomers, or a mixture of different polymers which contain a thermoplastic elastomer.

In the case of thermoplastic elastomers, it is possible in particular for elastic polymer chains to be incorporated into thermoplastic material. They can be processed in a purely physical process by a combination of high shear forces, application of heat and subsequent cooling.

If the plastics material is a thermoplastic elastomer material, the plastics material may preferably contain at least one of the following thermoplastic elastomers:
thermoplastic polyamide elastomers,
thermoplastic copolyester elastomers,
olefin-based thermoplastic elastomers, for example PP/EPDM,
thermoplastic styrene block copolymers, for example SBS, SEBS, SEPS, SEEPS and MBS,
urethane-based thermoplastic elastomers,
olefin-based thermoplastic vulcanizates or crosslinked thermoplastic elastomers, for example PP/EPDM.

Thermoplastic polyamide elastomers are also referred to in abbreviated form as TPA (or the obsolete form TPE-A).

Thermoplastic copolyester elastomers are also referred to in abbreviated form as TPC (or the obsolete form TPE-E).

Olefin-based thermoplastic elastomers are also referred to in abbreviated form as TPO (or the obsolete form TPE-O).

Thermoplastic styrene block copolymers are also referred to in abbreviated form as TPS (or the obsolete form TPE-S).

Urethane-based thermoplastic elastomers are also referred to in abbreviated form as TPU (or the obsolete form TPE-U).

Olefin-based thermoplastic vulcanizates or crosslinked thermoplastic elastomers are also referred to in abbreviated form as TPV (or the obsolete form TPE-V).

It may be advantageous if the elastomer material contains a natural or synthetic rubber and/or is produced from a natural or synthetic rubber.

It may be advantageous if the natural or synthetic rubber is an ethylene propylene diene monomer, an ethylene acrylate rubber, a silicone rubber and/or a fluororubber. It may be particularly advantageous if the natural or synthetic rubber is an ethylene acrylate rubber.

It may be advantageous if the contacting arrangement has a plastics profile, for example an elastic plastics profile and/or elastomer profile. It may be advantageous if, in a cross section of the plastics profile, the plastics profile extends into the contacting protrusion.

It may be particularly advantageous if the contacting arrangement has a plastics profile, for example an elastic plastics profile and/or elastomer profile, wherein, in a cross section of the plastics profile, the plastics profile extends into the contacting protrusion.

It may be advantageous if the cross section of the plastics profile is oriented orthogonally to a main extent direction of the contacting arrangement.

It may be advantageous if the plastics material, the elastomer material and/or the plastics profile is not foamed and/or is a solid plastics material, a solid elastomer material and/or a plastics profile consisting of solid plastics material or solid elastomer material.

For example, it may be the case that the plastics material is not foamed and/or is a solid plastics material.

For example, it may be the case that the elastomer material is not foamed and/or is a solid elastomer material.

It may be advantageous if pores are not discernible in a cross section of the plastics material or elastomer material, or, if pores are discernible, the area occupied by the pores is at most 70 %, preferably at most 50 %, in particular at most 30 %, for example at most 10 %, of the total area occupied by the plastics material or elastomer material. If pores are present, the total area occupied by the plastics material or elastomer material also encompasses the area occupied by the pores.

For example, it may be the case that the plastics profile is not foamed and/or is a plastics profile consisting of solid plastics material.

For example, it may be the case that the elastomer profile is not foamed and/or is an elastomer profile consisting of solid elastomer material.

It may be advantageous if a porosity of the plastics material, of the elastomer material, of the plastics profile or of the elastomer material is at most 60 %, preferably at most 40 %, particularly preferably at most 25 %, very particularly preferably at most 10 %, for example at most 5 %. The porosity is a dimensionless measurand which describes the ratio of cavity volume to total volume of the plastics material, of the elastomer material, of the plastics profile or of the elastomer profile. The porosity can be determined by measuring the density of the plastics material, of the elastomer material, of the plastics profile or of the elastomer profile and correlating this with the density of the contained polymer or of the contained polymers, including any provided additives.

It may be advantageous if the Shore hardness of the plastics material or of the elastomer material, for example of the plastics material or of the elastomer material of the plastics profile, is 30 Shore A to 90 Shore A, preferably 40 Shore A to 80 Shore A, for example 45 Shore A to 75 Shore A, in accordance with DIN ISO 7619-1.

It may be advantageous if the contacting protrusion

is an elevation which projects out of the main body

and/or

is an elevation which, in the cross section, projects out of the plastics profile portion of the plastics profile.

It may be advantageous if the elevation which projects out of the main body is a ridge projecting out of the main body or has a ridge projecting out of the main body.

It may be advantageous if the elevation and/or the ridge extends along the main body in a main extent direction of the contacting arrangement.

It may be advantageous if the elevation which, in the cross section, projects out of the plastics profile portion of the plastics profile is a ridge projecting out of the plastics profile portion or has a ridge projecting out of the plastics profile portion.

It may be advantageous if the elevation and/or the ridge extends along the plastics profile in a main extent direction of the contacting arrangement.

It may be advantageous if the contacting protrusion has at least one contacting protrusion portion in which the contacting protrusion narrows with increasing distance from the main body and/or from the plastics profile portion.

It may be advantageous if the narrowing of the contacting protrusion in the at least one contacting protrusion portion is discernible in the cross section in which the contacting protrusion projects out of the plastics profile portion of the plastics profile.

It may be advantageous if the contacting protrusion is a component contacting protrusion present on a component contacting side of the contacting arrangement, wherein the contacting arrangement has a further component contacting protrusion on the component contacting side.

It may be advantageous if the contacting zone is a component contacting zone, and the contacting arrangement has the component contacting zone on the component contacting protrusion, wherein the contacting arrangement has a further contacting zone, the further contacting zone is a further component contacting zone, and the contacting arrangement has the further component contacting zone on the further component contacting protrusion.

It may be advantageous if the first contacting zone is a first component contacting zone, and the contacting arrangement has the first component contacting zone on the component contacting protrusion, wherein the contacting arrangement has a further contacting zone, the further contacting zone is a further component contacting zone, and the contacting arrangement has the further component contacting zone on the further component contacting protrusion.

It may be advantageous if the component contacting protrusion and the further component contacting protrusion are spaced from one another on the component contacting side at least in a cross section of the contacting arrangement oriented orthogonally to the main extent direction of the contacting arrangement.

It may be advantageous if the component contacting protrusion and the further component contacting protrusion

are elevations which project out of the main body, in particular on the component contacting side of the main body, and which may for example be ridges projecting out of the main body or have ridges projecting out of the main body, wherein the elevations and/or ridges may extend along the main body in a main extent direction of the contacting arrangement,

and/or

are elevations which, in the cross section, project out of a plastics profile portion of the plastics profile, in particular on the component contacting side of the plastics profile portion, and which may for example be ridges projecting out of the plastics profile portion or have ridges projecting out of the plastics profile portion, wherein the elevations and/or ridges may extend along the plastics profile in a main extent direction of the contacting arrangement.

It may be advantageous if the component contacting side is a first component contacting side of the contacting arrangement, and the contacting arrangement has a second component contacting side.

It may be advantageous if the second component contacting side is formed oppositely in relation to the first component contacting side.

It may advantageously be the case that, when the contacting arrangement is arranged as intended between two components, the first component contacting side is in contact with one of the two components, and the second component contacting side is in contact with another of the components.

It may be advantageous if the contacting arrangement has one or more contacting protrusions, in particular one or two contacting protrusions, on the second component contacting side.

It may be advantageous if two component contacting protrusions which the contacting arrangement has on the second component contacting side are spaced from one another on the second component contacting side at least in a cross section of the contacting arrangement oriented orthogonally to the main extent direction of the contacting arrangement.

It may be advantageous if, in a cross section oriented orthogonally to the main extent direction of the contacting arrangement, the contacting arrangement has a total of four component contacting protrusions, wherein in each case two mutually spaced component contacting protrusions are formed on two mutually opposite component contacting sides of the contacting arrangement.

It may be advantageous if the contacting arrangement is H-shaped in a cross section of the contacting arrangement oriented orthogonally to the main extent direction of the contacting arrangement. It may be preferable if four component contacting protrusions form the four ends of the H-shaped cross section.

It may be advantageous if the four component contacting protrusions narrow toward the ends of the H-shaped cross section.

It may be advantageous if a central region arranged in the middle of the H-shaped cross section is thickened.

Particularly efficient contacting appears to be based inter alia on high contact pressures and thus an increased number of associated effective contact areas (so-called A-spots) via which the major proportion of the electrical current can flow. These appear to be promoted by the contacting protrusions described in conjunction with the invention, for example of the H-shaped cross section, and/or by a Shore hardness of the plastics material or of the elastomer material which lies in one of the ranges stated herein.

It may be advantageous if the contacting protrusion

is a contacting lip which projects out of the main body and which may be inclined and/or bent transversely to a main extent direction of the contacting arrangement, wherein it may be advantageous if the contacting lip extends along the main body in a main extent direction of the contacting arrangement,

and/or

is a contacting lip which projects out of a plastics profile portion of the plastics profile, wherein, in the cross section of the plastics profile, the plastics profile extends into the contacting lip and the contacting lip may be oriented obliquely in the cross section, wherein the contacting lip may extend along the plastics profile portion in a main extent direction of the contacting arrangement.

It may be advantageous if the contacting protrusion is the contacting lip which projects out of the main body, and if the contacting lip is inclined and/or bent transversely to a main extent direction of the contacting arrangement. It may be advantageous if the contacting lip which projects out of the main body is inclined and/or bent transversely to the main extent direction of the contacting arrangement such that, if the main body is oriented horizontally, the contacting lip entirely or partially extends over and/or covers a surface, facing toward the contacting lip, of the main body.

It may be advantageous if, in the cross section of the plastics profile, the plastics profile extends into the contacting lip, and the contacting lip is oriented obliquely in the cross section, in each case in such a way that a cavity extending along the contacting arrangement along the main extent direction is formed, with the contacting lip entirely or partially extending over and/or covering said cavity.

It may be advantageous if the contacting arrangement has a support protrusion. The support protrusion may advantageously be arranged and/or formed such that the contacting lip, if it is bent, can be supported by the support protrusion.

The support protrusion may advantageously be arranged and/or formed on the contacting arrangement such that the support protrusion is capable of supporting the contacting lip when the contacting lip bends for example as a result of contact with a component.

It may be advantageous if the contacting protrusion

extends from the main body, through a portion of the contacting protrusion which is spaced from the main body, to the main body, wherein the main body and the contacting protrusion enclose a cavity,

and/or

extends from a plastics profile portion of the plastics profile, through a portion of the contacting protrusion which is spaced from the plastics profile portion, to the plastics profile portion, wherein the plastics profile portion and the contacting protrusion enclose a cavity.

It may be advantageous if the contacting protrusion extends from the main body, arcuately through a portion of the contacting protrusion which is spaced from the main body, to the main body, wherein the main body and the arcuately extending contacting protrusion enclose a D-shaped cavity.

It may be advantageous if the contacting protrusion extends arcuately from a plastics profile portion of the plastics profile, through a portion of the contacting protrusion which is spaced from the plastics profile portion, to the plastics profile portion, wherein the plastics profile portion and the arcuately extending contacting protrusion enclose a D-shaped cavity.

For example, in particular in a cross section oriented orthogonally to the main extent direction of the contacting arrangement, the electrically conductive material may extend all or part of the way around the main body and/or around the plastics profile. In particular in the cross section oriented orthogonally to the main extent direction of the contacting arrangement, the electrically conductive material may extend all or part of the way around the main body and/or around the plastics profile and extend at least from the first contacting zone to the second contacting zone.

The main body and/or the plastics profile may be partially encased by the electrically conductive material. Partial encasement may be understood in particular to mean that an outer surface of the main body and/or of the plastics profile, which in particular may extend parallel to a main extent direction of the main body and/or of the plastics profile and delimit the main body and/or the plastics profile transversely to the main extent direction, is partially covered by the electrically conductive material.

The main body and/or the plastics profile may be fully encased by the electrically conductive material. Full encasement may be understood in particular to mean that an outer surface of the main body and/or of the plastics profile, which in particular may extend parallel to a main extent direction of the main body and/or of the plastics profile and delimit the main body and/or the plastics profile transversely to the main extent direction, is entirely covered by the electrically conductive material. The main body and/or the plastics profile can be regarded as being fully encased even if the electrically conductive material does not form a closed surface. For example, the aforementioned metallic lattices, metallic meshes or metallic fabrics generally do not form a closed surface because, owing to their structure, they have gaps, for example between mutually parallel threads or lattice regions, as a result of which the outer surface of the fully encased main body and/or plastics profile cannot be fully covered there.

The contacting arrangement described herein may advantageously be an EMC seal arrangement.

It may be advantageous if the EMC seal arrangement is capable of imparting a fluid-sealing action between two protective elements or components and providing shielding against electromagnetic radiation.

A fluid-sealing action can be understood here in particular to mean that a passage of a fluid through a gap between the protective elements and/or components is impeded or prevented.

For example, in particular in a cross section oriented orthogonally to the main extent direction of the contacting arrangement, the contacting arrangement may have a contacting portion and an additional portion.

The contacting portion may have the contacting zone, which may for example be the first contacting zone and/or may be the component contacting zone.

The contacting portion may have the second contacting zone.

The contacting portion may have the contacting protrusion.

The contacting portion may have the contacting protrusion portion.

The contacting portion may have the component contacting protrusion.

The contacting portion may extend from the first component contacting side to the second component contacting side.

The contacting portion may extend from the first component contacting side to the second component contacting side, and, as described herein, the second component contacting side may be formed oppositely in relation to the first component contacting side.

For example, the contacting protrusion may be a component contacting protrusion present in the contacting portion on a component contacting side of the contacting arrangement.

The additional portion may be any portion other than the contacting portion. The additional portion may for example promote and/or facilitate frictional and/or interlocking fixing of the contacting arrangement to a shielding layer of a protective element.

For example, the additional portion may be a sealing portion.

The sealing portion may have a sealing protrusion. The sealing protrusion may for example be a sealing lip or have a sealing lip.

For example, the plastics material may extend into the main body and into the contacting protrusion.

For example, the main body and the contacting protrusion may be constructed entirely or partially from the plastics material.

The sealing protrusion may for example be a sealing protrusion present in the sealing portion on a or the component contacting side of the contacting arrangement.

The sealing portion may extend from the first component contacting side to the second component contacting side.

The sealing portion may extend from the first component contacting side to the second component contacting side, and, as described herein, the second component contacting side may be formed oppositely in relation to the first component contacting side.

For example, the contacting protrusion may be a component contacting protrusion present in the contacting portion on a component contacting side of the contacting arrangement, and the sealing protrusion may be a sealing protrusion present in the sealing portion on the same component contacting side of the contacting arrangement. Optionally, a further contacting protrusion formed oppositely in relation to the component contacting protrusion may be formed in the contacting portion on an opposite component contacting side of the contacting arrangement. Optionally, a further sealing protrusion formed oppositely in relation to the sealing protrusion may be formed in the sealing portion on an opposite component contacting side of the contacting arrangement.

In a cross section oriented orthogonally to a main extent direction of the contacting arrangement, the electrically conductive material may extend from the first contacting zone to the second contacting zone. Said electrically conductive material may be guided and/or arranged and/or fixed along an outer surface of the main body, wherein the outer surface of the main body may be situated in the contacting portion.

It may be advantageous if the contacting arrangement is H-shaped in a cross section of the contacting arrangement oriented orthogonally to the main extent direction of the contacting arrangement. It may be preferable if two contacting protrusions of the contacting portion form two of the four ends of the H-shaped cross section, and two sealing protrusions of the sealing portion form two of the four ends of the H-shaped cross section.

It may be advantageous if the two contacting protrusions narrow toward the ends, formed by said contacting protrusions, of the H-shaped cross section.

It may be advantageous if the two sealing protrusions narrow toward the ends, formed by said sealing protrusions, of the H-shaped cross section.

It may be advantageous if the contacting zone is a first contacting zone and the contacting arrangement has a second contacting zone, wherein the first contacting zone is electrically conductively connected to the second contacting zone, wherein the contacting arrangement has a plurality of contacting units which can be placed in electrical contact with one another, or are in electrical contact with one another, in an intermediate contact zone.

It may be advantageous if the contacting arrangement has the first contacting zone on one of the contacting units and has the second contacting zone on another of the contacting units.

It may be advantageous if at least one of the plurality of contacting units is a metal profile or has a metal profile, wherein it may be advantageous if the metal profile is a U profile, for example an aluminum U profile.

It may be advantageous if the plurality of contacting units are two contacting units, wherein the two contacting units are metal profiles or have metal profiles,

wherein it may be advantageous if the metal profiles of the two contacting units are U profiles, for example aluminum U profiles.

It may be advantageous if the two open sides of the two U profiles face toward one another, and two legs of one of the two U profiles are in contact with the two legs of the other of the two U profiles. For example, the outer sides of the two legs of one of the two U profiles may be in contact with the inner sides of the two legs of the other of the two U profiles.

It may be advantageous if the two or more contacting units can be placed in electrical contact with one another, or are in electrical contact with one another, in the intermediate contact zone via at least one leg of at least one of the contacting units.

It may be advantageous if the intermediate contact zone is a frictional contact zone in which one of the contacting units is capable of rubbing against another of the contacting units if the first contacting zone is moved toward the second contacting zone and/or if the first contacting zone is moved away from the second contacting zone.

It may be advantageous if the contacting arrangement has a pressure-exerting device.

It may be advantageous if the pressure-exerting device is capable of building up an opposing force to a force which moves the two contacting zones toward one another. The force which moves the two contacting units toward one another may for example originate from two protective elements and/or components between which the contacting arrangement is arranged, in particular if the two protective elements and/or components are moved toward one another. It may be advantageous if the opposing force contributes to better contacting of the protective elements and/or components in the two contacting zones.

It may be advantageous if the pressure-exerting device is capable of enhancing, ensuring and/or stabilizing electrical contact, in the intermediate contact zone, for example in the frictional contact zone, between the contacting units which can be placed in electrical contact or are in electrical contact in the intermediate contact zone, for example in the frictional contact zone.

It may be advantageous if one of the contacting units can be pressed or is pressed against another of the contacting units in the intermediate contact zone, for example in the frictional contact zone, by the pressure-exerting device.

It may be advantageous if the pressure-exerting device has a pressure-exerting spring element by means of which the opposing force can be built up.

It may be advantageous if the pressure-exerting device has an intermediate contact-promoting element. In particular, it is advantageously possible for the electrical contact in the intermediate contact zone, for example frictional contact zone, to be able to be enhanced, ensured and/or stabilized by means of the intermediate contact-promoting element.

The intermediate contact-promoting element may for example be an elastic element.

The intermediate contact-promoting element may for example be arranged in at least one of the contacting units, for example metal profile and/or U profile.

It may be advantageous if the pressure-exerting device or the intermediate contact-promoting device is capable of pressing at least one flexible region, for example one leg, of one of the contacting units against another of the contacting units, and the electrical contact in the intermediate contacting zone, for example frictional contact zone, can thus be enhanced, ensured and/or stabilized.

It may be advantageous if the contacting arrangement has a contacting protrusion described herein, for example on at least one of the plurality of contacting units, wherein the contacting arrangement has the contacting zone, for example the first contacting zone, on the contacting protrusion.

The object is achieved according to the invention by means of the protective element according to the independent claim directed thereto.

The protective element is a protective element for increasing electromagnetic compatibility. The protective element has the following:

a shielding layer for protecting against electrical, magnetic or electromagnetic fields, and

a contacting arrangement described herein, which is in electrical contact with the shielding layer.

It may be advantageous if the contacting arrangement of the protective element is a contacting arrangement which has a contacting zone, wherein the contacting arrangement is arranged and/or oriented such that the contacting arrangement narrows toward the contacting zone.

It may be advantageous if the contacting arrangement is arranged and/or oriented such that the contacting arrangement narrows from the shielding layer toward the contacting zone, in particular toward the first contacting zone, at least in a portion of the contacting arrangement which is situated between the shielding layer and the contacting zone, in particular between the shielding layer and the first contacting zone.

The narrowing of the contacting arrangement toward the contacting zone, in particular toward the first contacting zone, may be understood in particular to mean that the contacting protrusion is wider at a base of the contacting protrusion, in particular in a cross section oriented orthogonally to a main extent direction of the contacting arrangement, than at an end of the contacting protrusion, at which the contacting zone, in particular the first contacting zone, is situated.

For example, in the cross section, the contacting protrusion may narrow in a wedge shape and/or in a trapezoidal shape from the base toward the end.

It may be advantageous if the contacting arrangement defines, on the protective element, a peripheral contact contour for producing electrical contact, wherein the contact contour may be fully encircling or may have one or more discontinuities.

It may be advantageous if the contacting arrangement defines, on the protective element, a peripheral contact contour for producing electrical contact, wherein the contact contour is fully encircling.

It may be advantageous if the contacting arrangement and the peripheral contact contour have the following properties:

The contact contour extends in a plane, or, if the contact contour does not extend in a plane, the profile of the contact contour can be described by two mutually parallel planes which are spaced to the least possible extent, wherein the contact contour extends entirely between the two planes,

and

the contacting arrangement narrows toward the contact contour in a direction orthogonal to the plane or to the two planes.

It may be advantageous if the contacting arrangement narrows toward the contact contour, in the direction orthogonal to the plane or to the two planes, in a cross section of the contacting arrangement or of the plastics profile. It may be advantageous if the contacting arrangement narrows toward the contact contour, in the direction orthogonal to the plane or to the two planes, in the contacting protrusion, wherein the contacting arrangement may in particular narrow toward the contacting zone in the contacting protrusion.

It may be advantageous if the contact contour is a contact contour formed by a corner region of the contacting arrangement. The corner region may be a corner region which extends along the contacting arrangement in the main extent direction of the contacting arrangement. The corner region may be a rounded corner region. For example, it may be the case that the contacting arrangement does not have a contacting protrusion, or the corner region is not a corner region of a contacting protrusion. The corner region may advantageously be a corner region of the main body or of the plastics profile. It may be advantageous if the contacting arrangement is tilted relative to the direction which is orthogonal to the plane or to the two planes.

It may be advantageous if, in the cross section of the contacting arrangement and/or of the plastics profile, the corner region projects out along the direction which is orthogonal to the plane or to the two planes, and/or, in the cross section, said corner region forms an end of the contacting arrangement along the direction which is orthogonal to the plane or to the two planes, in particular an end which, during the installation of the protective element on a component, is capable of coming into contact first with a surface, facing toward the protective element, of the component.

It may be advantageous if the protective element described herein, in particular the protective element which has the shielding layer and the contacting arrangement in electrical contact with the shielding layer, is a component of a housing and/or is a delimiting element for delimiting an interior space with respect to an exterior space.

It may be advantageous if the protective element, the delimiting element and/or the component has a barrier element. It may be advantageous if the shielding layer fully or partially covers the barrier element, the shielding layer is arranged on the barrier element, and/or the shielding layer forms a layer composite together with the barrier element.

It may be advantageous if the protective element, the delimiting element and/or the component has a further barrier element. It may be advantageous if the shielding layer fully or partially covers the further barrier element, the shielding layer is arranged on the further barrier element, and/or the shielding layer forms a layer composite together with the further barrier element.

For example, the shielding layer may extend between the two barrier elements at least in certain portions.

The shielding layer may be arranged on the barrier elements.

The shielding layer may form, for example, a layer composite together with the barrier elements.

It may be advantageous if the protective element is an underbody protection element and/or a battery housing part.

It may be advantageous if the protective element has a side wall and an interior space, wherein the interior space is entirely or partially surrounded by the side wall.

It may be advantageous if the side wall is formed entirely or partially by the barrier element.

It may be advantageous if the side wall is formed entirely or partially by the barrier element, in particular by the barrier elements and the at least one shielding layer which extends between the barrier elements at least in certain portions.

It may be particularly advantageous if the protective element is pot-shaped and/or trough-shaped. One of the barrier elements may be an inner barrier element, and the other of the barrier elements may be an outer barrier element of the pot-shaped and/or trough-shaped protective element.

It may be advantageous if the shielding layer fully or partially surrounds an interior space of the trough-shaped and/or pot-shaped protective element, and the shielding layer extends into an edge region of the protective element, wherein the contacting arrangement is in electrical contact with the shielding layer in the edge region.

The protective elements may have a contacting arrangement receiving zone in which or on which the contacting arrangement is arranged.

The contacting arrangement receiving zone may have a contacting arrangement receiving depression in which the contacting arrangement is entirely or partially, in particular partially, received.

The contacting arrangement receiving zone may be a recess in a barrier element or in one of the barrier elements or may be delimited by the two barrier elements. The contacting arrangement receiving zone may for example be delimited by the two barrier elements.

For example, the contacting arrangement receiving zone may be delimited by the inner barrier element in a direction leading toward the interior space, and may be delimited by the outer barrier element in another direction. The other direction may for example be opposite to the direction leading toward the interior space, or orthogonal to the direction leading toward the interior space.

The shielding layer may for example extend into the contacting arrangement receiving zone or extend through the contacting arrangement receiving zone.

The contacting arrangement may be in electrical contact with the shielding layer in the contacting arrangement receiving zone.

Optionally, the contacting arrangement receiving zone may have a sealing compartment and a contacting compartment.

The second contacting zone may be in electrical contact with the shielding layer in the contacting compartment.

A or the sealing protrusion of the sealing portion may project into the sealing compartment.

The sealing portion may for example have two mutually opposite sealing protrusions, wherein one of the sealing protrusions projects into the sealing compartment.

An intermediate support portion may project into the contacting arrangement receiving zone and separate the sealing compartment from the contacting compartment. An intermediate portion of the contacting arrangement may be arranged on the intermediate support portion. The intermediate portion may be a portion of the contacting arrangement which is situated between the sealing portion and the contacting portion.

The protective element may have not only the contacting arrangement receiving zone but also a sealing element receiving zone in which a sealing element can be arranged.

The sealing element receiving zone may have a sealing element receiving depression in which the sealing element is partially received.

The sealing element receiving zone may extend along the contacting arrangement receiving zone and with a spacing to the contacting arrangement receiving zone.

The sealing element receiving zone may be further remote from the interior space than the contacting arrangement receiving zone.

The sealing element receiving zone may for example extend substantially parallel to the contacting arrangement receiving zone.

The object is achieved according to the invention by means of the protective arrangement according to the independent claim directed thereto.

The protective arrangement is a protective arrangement for increasing electromagnetic compatibility, wherein the protective arrangement has at least two protective elements which fully or partially enclose an interior space of the protective arrangement, wherein

at least one of the at least two protective elements is a protective element described herein,

and/or

the at least two protective elements are in electrical contact with one another via a contacting arrangement described herein, wherein electrical contact with at least one shielding layer of one of the at least two protective elements is established via the contacting arrangement, wherein it may be advantageous if electrical contact between a shielding layer of one of the at least two protective elements and a shielding layer of another of the at least two protective elements is established via the contacting arrangement.

It may be advantageous if at least one of at least two electrical contacts between the contacting arrangement and at least one of the at least two protective elements is established via an inclined surface of the at least one of the at least two protective elements.

It may be advantageous if at least one portion of the inclined surface is inclined relative to the direction which is orthogonal to the plane or to the two planes, wherein the angle of inclination may preferably be 89° to 20°, particularly preferably 85° to 30°, very particularly preferably 80° to 45°, for example 75° to 50°.

It may be advantageous if the electrical contact, in particular the electrical contact established via the inclined surface of the at least one of the at least two protective elements, is established via the contacting zone and/or via the peripheral contact contour.

In conjunction with the invention, it was found that certain contacting arrangements or EMC seal arrangements are particularly highly suitable for connecting two protective elements, delimiting elements and/or components whilst providing a strong electromagnetic shielding action.

For example, the contacting arrangement and/or EMC seal arrangement can be arranged on a flange region of a protective element, delimiting element and/or component.

The contacting arrangement and/or EMC seal arrangement can provide an electrically conductive connection of the protective elements, delimiting elements and/or components with a low electrical resistance and/or low impedance, and at the same time ensure height compensation, in particular compensation for unevennesses in order to avoid the formation of openings in the electromagnetic shield.

In particular, the invention can make it possible, even without the use of spring elements, to permanently maintain a restoring force which is advantageous for the electrical contacting – this being substantially unaffected by relaxation behavior and/or aging that can be observed in the case of known contacting arrangements.

Features described in conjunction with one subject matter according to the invention can self-evidently also form features of another subject matter according to the invention described herein. In particular, the contacting arrangement, the protective element and the protective arrangement each constitute a subject matter according to the invention.

Further preferred features and/or advantages of the invention are discussed in the following description and shown in the illustration of exemplary embodiments in the drawings.

### BRIEF DESCRIPTION OF THE DRAWINGS

FIG. 1: is a highly simplified schematic illustration of a protective arrangement in the form of a housing;

FIG. 2: shows examples of contacting arrangements designed as spring elements;

FIG. 3: is an illustration of a contacting arrangement having a main body consisting of plastics material;

FIG. 4: shows a cross section through a contacting arrangement;

FIG. 5: shows a cross section through a contacting arrangement;

FIG. 6: shows a cross section through a contacting arrangement;

FIG. 7: is a graphical illustration of measurement results;

FIG. 8: shows a cross section through a contacting arrangement;

FIG. 9: shows a cross section through a contacting arrangement;

FIG. 10: shows a cross section through a contacting arrangement;

FIG. 11: shows a cross section through a contacting arrangement;

FIG. 12: shows a cross section through a contacting arrangement;

FIG. 13: is a highly simplified schematic illustration of a protective element;

FIG. 14: shows a section through the protective element from FIG. 13 along the line XIV-XIV;

FIG. 15: shows a section through an alternative embodiment of the protective element from FIG. 13 along the line XV-XV;

FIG. 16: is a schematic illustration of a detail of a protective arrangement;

FIG. 17: is a schematic illustration of a detail of a protective arrangement;

FIG. 18: is a graphical illustration of measurement results;

FIG. 19: is a graphical illustration of measurement results;

FIG. 20: is a graphical illustration of measurement results;

FIG. 21: shows a detail of a cross section through a protective arrangement;

FIG. 22: shows a detail of a cross section through a protective arrangement; and

FIG. 23: shows a detail of a cross section through a protective arrangement.

### DETAILED DESCRIPTION OF THE DRAWINGS

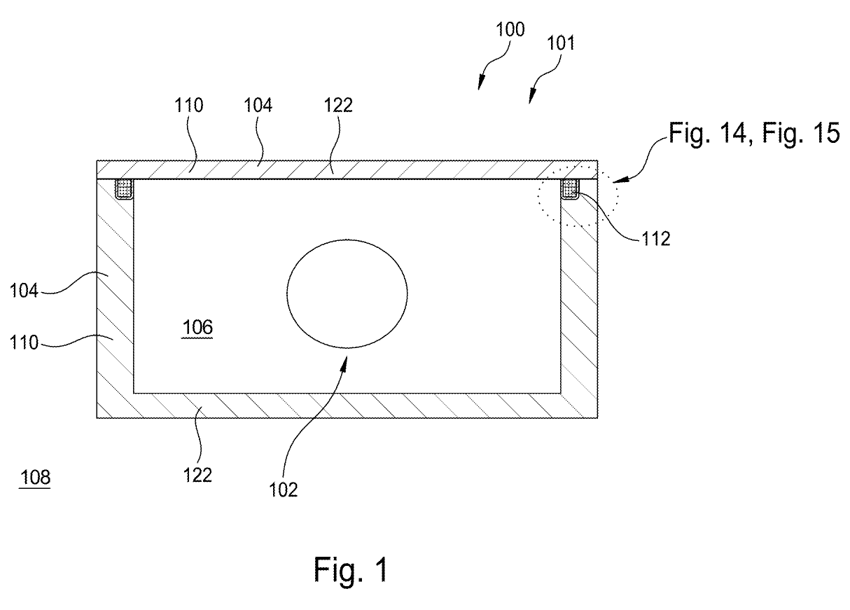

FIG. 1 is a highly simplified schematic illustration of a housing 100 and a source 102 of electromagnetic radiation, said source being situated in the housing 100.

The housing 100 has two delimiting elements 104. The two delimiting elements 104 delimit an interior space 106 of the housing with respect to an exterior space 108 surrounding the housing.

The two delimiting elements 104 illustrated in FIG. 1 may optionally have a shielding layer (not illustrated) for protecting against electrical, magnetic or electromagnetic fields.

The two delimiting elements 104 may then each be protective elements 110 for increasing electromagnetic compatibility.

In FIG. 1, a contacting arrangement 112 is shown at a transition from the protective element 110 illustrated at the top to the protective element 110 illustrated at the bottom. The contacting arrangement 112 is a contacting arrangement 112 for electrically contacting a protective element 110 for increasing electromagnetic compatibility.

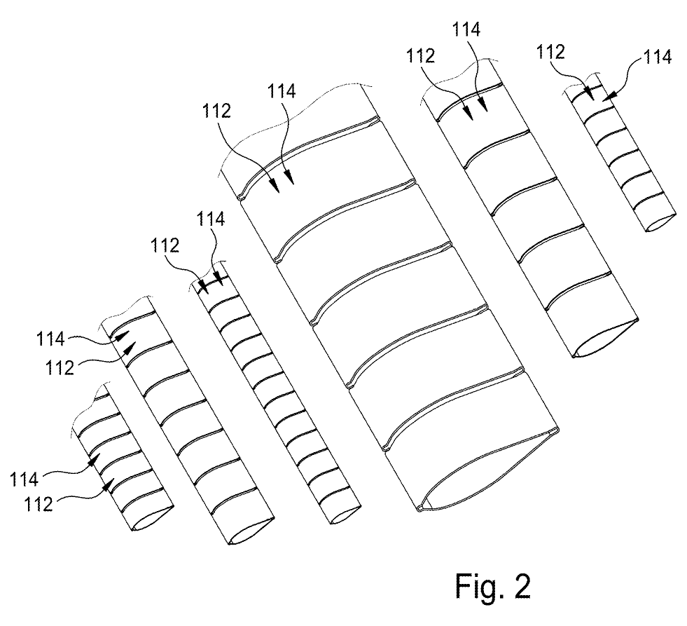

The following FIGS. 2-6 and 8-12 show examples of contacting arrangements 112 for electrically contacting a protective element 110 for increasing electromagnetic compatibility.

The contacting arrangements 112 illustrated in FIG. 2 are spring elements 114.

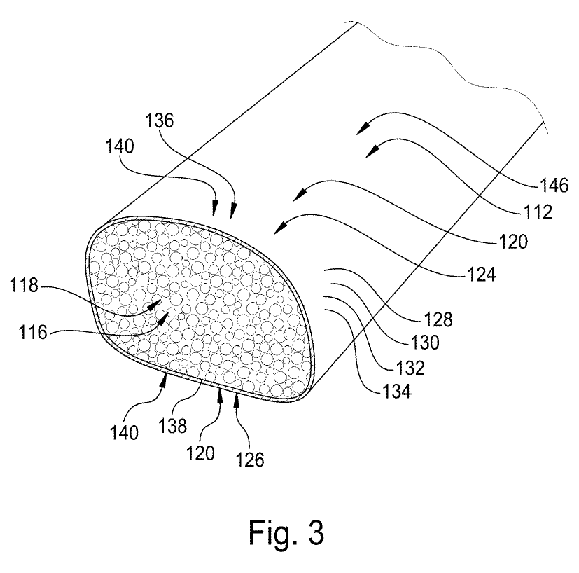

The contacting arrangement 112 illustrated in FIG. 3 has a main body 116. The contacting arrangement 112 illustrated in said figure has a plastics material 118. The plastics material forms the main body 116. The main body is constructed from the plastics material 118. In the contacting arrangement 112 illustrated in FIG. 3, the plastics material is foamed. It has a high proportion of pores.

The contacting arrangement 112 illustrated in FIG. 3 has a contacting zone 120. The contacting zone 120 illustrated in FIG. 3 can be placed in electrical contact with a component 122. Examples of such components 122 are the delimiting elements 104 or protective elements 110 illustrated in FIG. 1. These form components 122 of the housing 100.

The contacting arrangement 112 illustrated in FIG. 3 has a first contacting zone 124 and a second contacting zone 126. The first contacting zone 124 is electrically conductively connected to the second contacting zone 126. In the contacting arrangement 112 illustrated in FIG. 3, the first contacting zone 124 and the second contacting zone 126 are connected by means of an electrically conductive material 128. The electrically conductive material 128 is a sheet material 130. In the example shown, it is a sheet aluminum material 132, for example an aluminum foil 134. In FIG. 3 and other figures, the electrically conductive material 128, in particular the sheet material 130, for example the aluminum foil 134, is in some cases illustrated with an exaggerated thickness.

The contacting arrangement 112 shown in FIG. 3 has a first surface region 136 and a second surface region 138. The first contacting zone 124 is formed on the first surface region 136. The second contacting zone 126 is formed on the second surface region 138. The first surface region 136 and the second surface region 138 are mutually spaced surface portions 140 of the electrically conductive material 128.

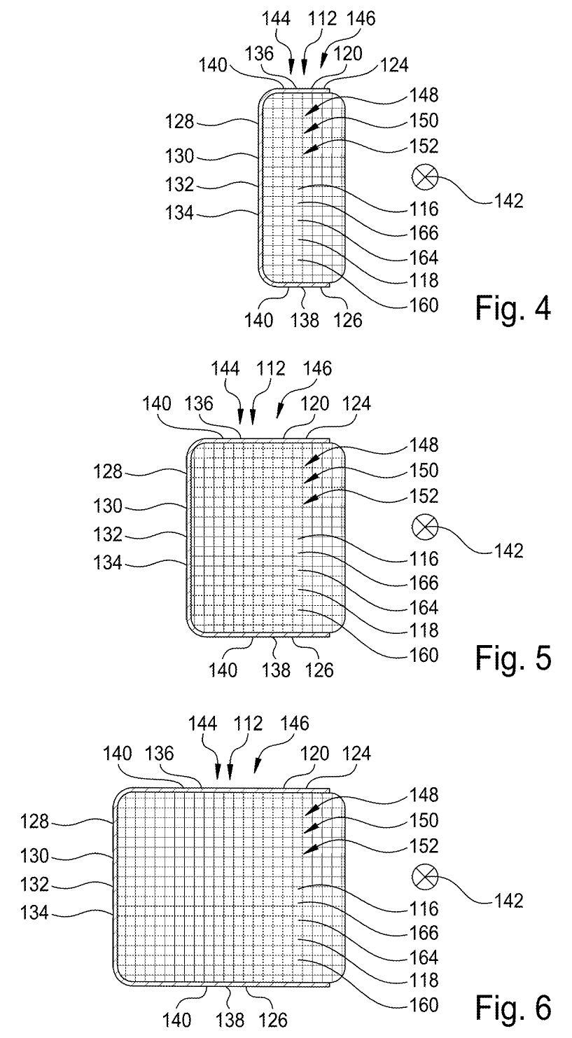

FIG. 4, 5, 6, 9, 10, 11 and 12 are sectional illustrations of contacting arrangements 112 for electrically contacting a protective element, which is not illustrated in any of these figures. The protective element could in each case be, for example, a protective element of a housing 100 schematically illustrated in FIG. 1, for example a protective element of one of the two components 122 of said housing, in particular a protective element 110 of one of the two delimiting elements 104 illustrated in FIG. 1.

The protective element 110 may then advantageously be a protective element 110 for increasing electromagnetic compatibility.

FIGS. 4-6 and 9-12 each show cross sections 144 oriented orthogonally to a main extent direction 142 of the illustrated contacting arrangements 112.

The contacting arrangements 112 illustrated in FIGS. 4-6 and 9-12 are EMC seal arrangements 146, like the contacting arrangement 112 illustrated in FIG. 3.

The contacting arrangements 112 illustrated in FIGS. 4-6 and 9-12 also have a contacting zone 120. The contacting zone 120 can be placed in electrical contact with a component 122 against which the contacting arrangement 112 can come to lie.

The contacting zones 120 shown in FIGS. 4-6 and 9-12 are first contacting zones 124. The contacting arrangements 112 shown in said figures have a second contacting zone 126. The first contacting zone 124 is electrically conductively connected to the second contacting zone 126.

The contacting arrangements 112 shown in FIGS. 4-6 and 9-12 have a first surface region 136 and a second surface region 138. The first contacting zone 124 is formed on the first surface region 136, and the second contacting zone 126 is formed on the second surface region 138.

The first contacting zones 124 and second contacting zones 126 shown in FIG. 4 to 6 and 9 to 12 are in each case connected by means of an electrically conductive material 128. The electrically conductive material 128 in each case is a sheet material 130. It may for example be a sheet aluminum material 132, for example aluminum foil. The first surface region 136 and the second surface region 138 are in each case mutually spaced surface portions 140 of the electrically conductive material 128.

The contacting arrangements 112 shown in FIGS. 4-6 and 9-12 also each have a main body 116. The contacting arrangements 112 shown in said figures each have a plastics material 118.

The contacting arrangements 112 shown in FIGS. 4-6 and 9-12 have a plastics profile 148. The plastics profile may for example be an elastic plastics profile 150 and/or an elastomer profile 152.

The height of the cross sections 144 illustrated in FIG. 4, 5 and 6 may for example be approximately 10 mm. The width of the cross section illustrated in FIG. 4 may for example be approximately 4 mm, the width of the cross section illustrated in FIG. 5 may for example be approximately 7 mm, and the width of the cross section illustrated in FIG. 6 may for example be approximately 10mm. The stated dimensions may relate in particular to a non-compressed state of the main bodies 116 and/or plastics profiles 148, in which the contacting arrangements are not arranged between components 122.

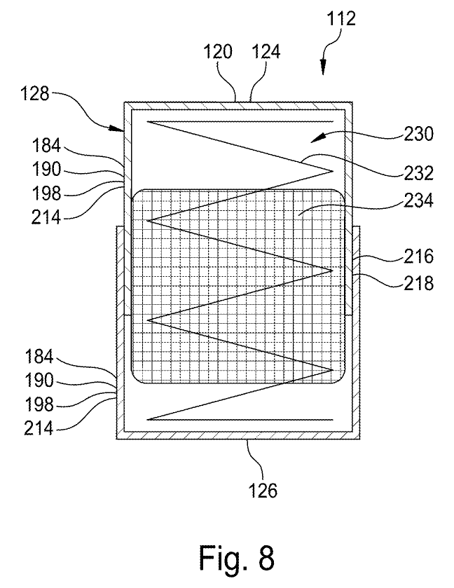

FIG. 8 shows a contacting arrangement 112. The contacting arrangement has a contacting zone 120. The contacting zone 120 is a first contacting zone 124. The contacting arrangement 112 has a second contacting zone 126, wherein the first contacting zone 124 is electrically conductively connected to the second contacting zone 126. The first contacting zone 124 and the second contacting zone 126 are connected by means of an electrically conductive material 128.

The contacting arrangement 112 shown in FIG. 8 is an example of a contacting arrangement 112 which has a plurality of contacting units 184. In the example shown, the contacting units are metal profiles 190. The metal profiles 190 may in particular be U profiles 198, for example aluminum U profiles 214.

The contacting arrangement 112 may have the first contacting zone 124 on one of the contacting units 184 and have the second contacting zone 126 on another of the contacting units 184.

The electrically conductive material 128 by means of which the first contacting zone 124 and the second contacting zone 126 are connected may be formed by one or more materials of the contacting units 184. Said contacting units 184 are in electrical contact with one another in an intermediate contact zone 216 such that the first contacting zone 124 and the second contacting zone 126 are connected by means of the electrically conductive material 128. The intermediate contact zone 216 may for example be a frictional contact zone 218.

The contacting arrangement 112 shown in FIG. 8 has a pressure-exerting device 230. The pressure-exerting device 230 is capable of building up an opposing force to a force which moves the two contacting zones 124 and 126 toward one another.

Alternatively or in addition, the pressure-exerting device 230 is capable of enhancing, ensuring and/or stabilizing electrical contact between contacting units 184 in the intermediate contact zone 216, for example frictional contact zone 218. For example, for this purpose, one contacting unit 184 can be pressed against another contacting unit 184 in the intermediate contact zone 216, for example frictional contact zone 218, by the pressure-exerting device 230.

The example of a pressure-exerting device 230 shown in FIG. 8 has a pressure-exerting spring element 232 by means of which, in particular, the opposing force can be built up, and has an intermediate contact-promoting element 234 by means of which, in particular, the electrical contact in the intermediate contact zone 216, for example frictional contact zone 218, can be enhanced, ensured and/or stabilized. In the example shown, the pressure-exerting spring element 232 and the intermediate contact-promoting element 234 are different components of the contacting arrangement 112. The two effects of the two elements 232 and 234 could however be achieved instead by means of a pressure-exerting device 230 constructed from only one component.

The contacting arrangements 112 illustrated in FIGS. 4-6 and 8 do not have a contacting protrusion. It may however be advantageous if a contacting arrangement 112 has a contacting protrusion 154.

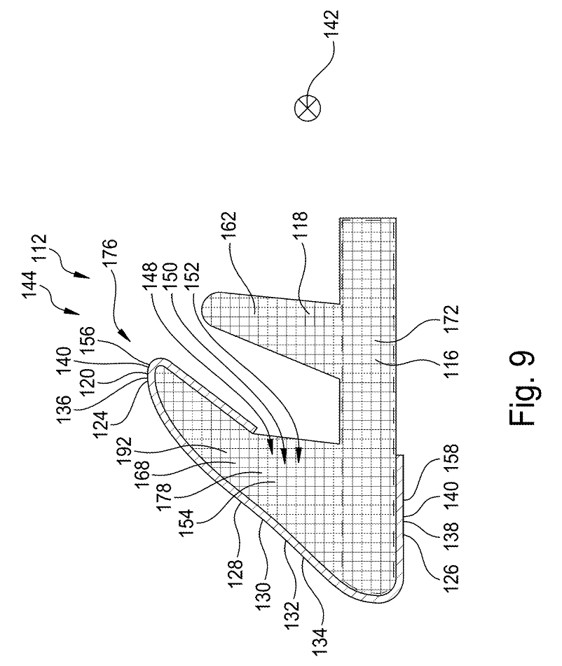

Examples of contacting arrangements 112 which have a contacting protrusion 154 are the contacting arrangements 112 illustrated in FIGS. 9-12.

The contacting arrangements 112 illustrated in FIGS. 9-12 have an apical surface region 156 and a basal surface region 158. In each of these figures, the first surface region 136 is the apical surface region 156, and the second surface region 138 is the basal surface region 158. The first contacting zone 124 is formed on the apical surface region 156. The second contacting zone 126 is formed on the basal surface region 158.

FIGS. 9-12 show contacting arrangements which have a plastics material 118, wherein the plastics material extends into the main body 116 and into the contacting protrusion 154.

The main body 116 and the contacting protrusion 154 are constructed from the plastics material 118.

As can be clearly seen from FIGS. 9-12, in each of the contacting arrangements 112 illustrated in said figures, the contacting protrusions 154 project out of the main body 116.

In each of the contacting arrangements 112 shown in FIGS. 4-6 and 9-12, the plastics material 118 is an elastomer material 160. The contacting arrangements 112 illustrated in said figures are examples of contacting arrangements 112 which have a plastics profile 148. By contrast to the contacting arrangements shown in FIGS. 4-6, the contacting arrangements 112 shown in FIGS. 9-12 are contacting arrangements 112 in which, in a cross section 144 of the plastics profile 148, the plastics profile 148 extends into the associated contacting protrusion 154.

It may for example be the case that, in each of the contacting arrangements shown in FIGS. 4-6 and 9-12, the plastics material 118, the elastomer material 160 and/or the plastics profile 148 is not foamed and/or is a solid plastics material 164, a solid elastomer material 166 and/or a plastics profile 148 consisting of solid plastics material 164.

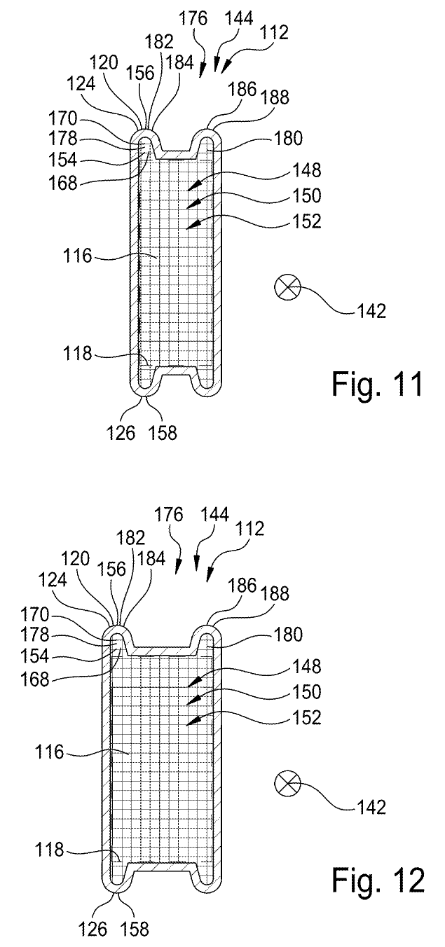

In each of the contacting arrangements 112 shown in FIG. 9 to 12, the contacting protrusion 154 is an elevation 168 which projects out of the main body 116. Each elevation 168 may for example be a ridge 170 projecting out of the main body 116 or have a ridge 170 projecting out of the main body 116. For example, the elevation 168 illustrated in FIG. 9 extends along the main body 116 in the main extent direction 142 of the contacting arrangement 112. For example, the ridge 170 illustrated in FIG. 11 extends along the main body 116 in the main extent direction 142 of the contacting arrangement 112 illustrated in said figure.

The contacting protrusions 154 illustrated in FIGS. 9-12 are elevations 168 which, in the associated cross section 144, project out of a plastics profile portion 172 of the associated plastics profile 148. The elevations 168 may for example be ridges 170 projecting out of the plastics profile portion 172 (see for example FIG. 11) or have a ridge projecting out of the associated plastics profile portion 172. Advantageously, each elevation 168 and/or each ridge 170 may extend along the plastics profile 148 in the main extent direction 142 of the contacting arrangement 112.

In each of FIGS. 9-12, dash-dotted lines have been used to highlight the main body 116 and the plastics profile portions 172 out of which the associated elevations 168 project.

It may be advantageous if the contacting protrusion 154 is a component contacting protrusion 178 present on a component contacting side 176 of the contacting arrangement 112. FIG. 11 and 12 show examples of contacting arrangements 112 in which the contacting protrusion 154 is a component contacting protrusion 178 present on a component contacting side 176 of the associated contacting arrangement, wherein the contacting arrangements 112 each have a further component contacting protrusion 180 on the component contacting side 176.

For example, in the contacting arrangements 112 shown in FIG. 11 and 12, the contacting zone 120 may be a component contacting zone 182, and the contacting arrangement 112 may have the component contacting zone 182 on the component contacting protrusion 178. The contacting arrangements 112 shown in FIG. 11 and 12 have a further contacting zone 186, wherein the further contacting zone 186 is a further component contacting zone 188. The contacting arrangements 112 shown in said figures have the further component contacting zone 188 on the further component contacting protrusion 180.

It may be advantageous if, as illustrated in FIG. 11 and 12, the component contacting protrusion 178 and the further component contacting protrusion 180 are spaced from one another on the component contacting side 176 in the cross section 144 of the contacting arrangement 112 oriented orthogonally to the main extent direction 142 of the contacting arrangement 112, as illustrated in said figures.

FIG. 11 and 12 illustrate that the component contacting protrusion 178 and the further component contacting protrusion 180 are for example elevations 168 which project out of the main body 116, in particular on the component contacting side 176 of the main body 116, and which may for example be ridges 170 projecting out of the main body 116 or have ridges projecting out of the main body 116, wherein the elevations 168 and/or ridges 170 may extend along the main body 116 in the main extent direction 142 of the contacting arrangement 112.

In the contacting arrangements 112 illustrated in FIG. 11 and 12, the component contacting protrusion 178 and the further component contacting protrusion 180 are elevations 168 which, in the cross section 144, project out of the plastics profile portion 172 of the plastics profile 148, and which may for example be ridges 170 projecting out of the plastics profile portion or have ridges 170 projecting out of the plastics profile portion 172, wherein the elevations 168 and/or the ridges 170 may extend along the plastics profile 148 in the main extent direction 142 of the contacting arrangement 112.

FIG. 9 shows an example of a contacting arrangement 112 in which the contacting protrusion 154 is a contacting lip 192 which projects out of the main body 116 and which is inclined and/or bent transversely to a main extent direction 142 of the contacting arrangement 112, wherein it may be advantageous if the contacting lip 192 extends along the main body 116 in a main extent direction 142 of the contacting arrangement 112.

FIG. 9 shows an example of a contacting arrangement 112 in which the contacting protrusion 154 is a contacting lip 192 which projects out of a plastics profile portion 172 of the plastics profile 148, wherein, in the cross section 144 of the plastics profile 148, the plastics profile 148 extends into the contacting lip 192 and the contacting lip 192 is oriented obliquely in the cross section 144, wherein the contacting lip 192 may extend along the plastics profile portion 172 in a main extent direction 142 of the contacting arrangement 112.

FIG. 9 shows an example of a contacting arrangement 112 which has a support protrusion 162. The support protrusion 162 may advantageously be arranged and/or formed such that the contacting lip 192, if it is bent, can be supported by the support protrusion 162.

FIG. 9 shows an example of a contacting arrangement 112 in which the support protrusion 162 is arranged and/or formed on the contacting arrangement 112 such that the support protrusion 162 is capable of supporting the contacting lip 192 when the contacting lip 192 bends for example as a result of contact with a component 122.

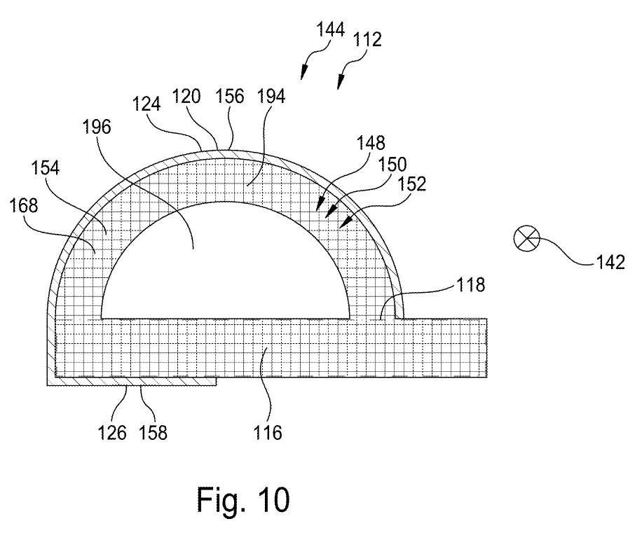

FIG. 10 shows an example of a contacting arrangement 112 in which the contacting protrusion 154 extends from the main body 116, through a portion 194 of the contacting protrusion 154 which is spaced from the main body 116, to the main body 116, wherein the main body 116 and the contacting protrusion enclose a cavity 196.

FIG. 10 shows an example of a contacting arrangement 112 in which the contacting protrusion extends from a plastics profile portion 172 of the plastics profile 148, through a portion 194 of the contacting protrusion 154 which is spaced from the plastics profile portion 172, to the plastics profile portion 172, wherein the plastics profile portion 172 and the contacting protrusion 154 enclose a cavity 196.

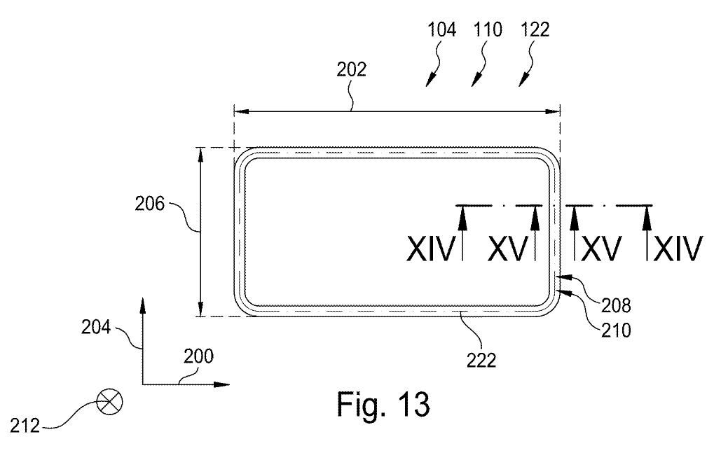

FIG. 13 is a simplified schematic illustration of a protective element 110 for increasing electromagnetic compatibility. The protective element 110 illustrated in FIG. 13 may for example be one of the delimiting elements 104 schematically illustrated in FIG. 1. It may be one of the components 122 of the housing 100 which are illustrated in said figure.

In FIG. 13, the viewer's viewing direction is along an installation direction 212 in which the protective element 110 can be installed. The protective element illustrated in FIG. 13 has an extent 202 in a first direction 200. Said protective element has an extent 206 in a second direction 204 oriented orthogonally to the first direction 200. The installation direction 212 along which a viewer views the protective element 110 is oriented orthogonally to the first direction and orthogonally to the second direction. The protective element 110 has an attachment surface 208 and/or contacting surface 210 which faces toward the viewer viewing the protective element 110 along the installation direction 212.

The attachment surface 208 and/or contacting surface 210 may optionally lie in a plane which is orthogonally intersected by a straight line running along the installation direction.

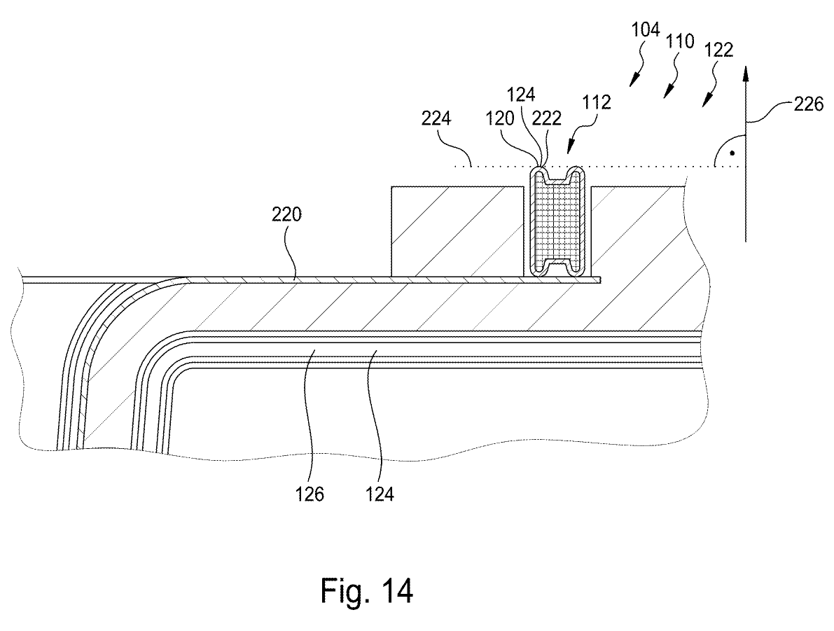

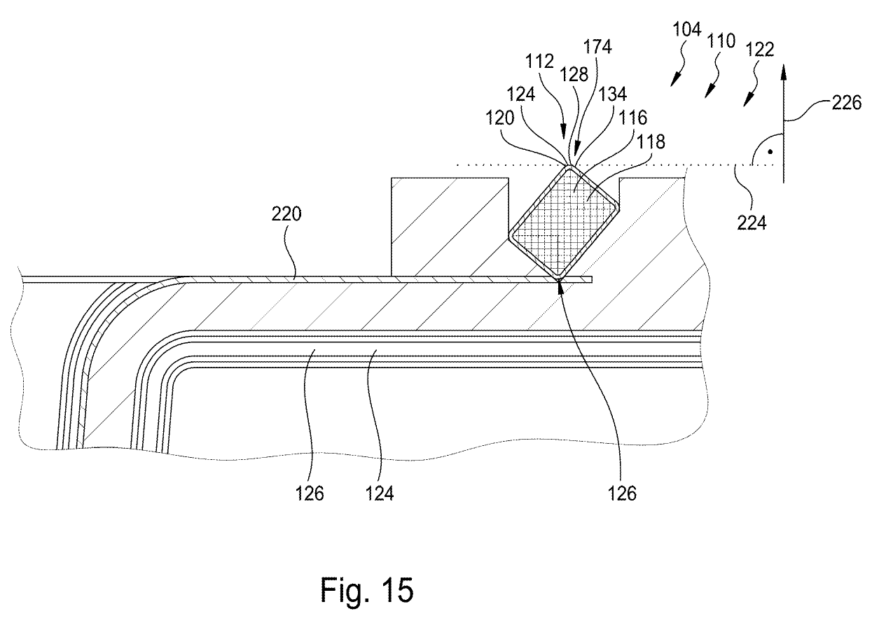

FIG. 14 and 15 show possible configurations of the protective element 110 illustrated in FIG. 13. For example, FIG. 14 shows a section, along the line XIV-XIV, through an edge region of a protective element 110 illustrated in FIG. 13.

FIG. 15 shows a section, along the line XV-XV, through an edge region of a protective element 110 illustrated in FIG. 13.

FIG. 14 and 15 each show only a detail of a section through a protective element 110 for increasing electromagnetic compatibility, wherein the protective element 110 has a shielding layer 220 for protecting against electrical, magnetic or electromagnetic fields and has a contacting arrangement 112 which is in electrical contact with the shielding layer 220.

The contacting arrangement 112 of the protective element 110 illustrated in FIG. 14 is a contacting arrangement according to FIG. 12.

The contacting arrangement 112 of the protective element 110 illustrated in FIG. 15 is similar to the contacting arrangement 112 illustrated in FIG. 5. In the case of the contacting arrangement 112 illustrated in FIG. 15, by contrast to the contacting arrangement 112 illustrated in FIG. 5, the electrically conductive material, for example the aluminum foil 134, is arranged such that plastics material 118 of the main body 116 is fully encased.

In the case of the protective element 110 illustrated in FIG. 14, the contacting arrangement 112 is arranged such that the contacting arrangement 112 narrows toward the contacting zone 120.

The contacting arrangement defines, on the protective element 110, a peripheral contact contour 222 for producing electrical contact. The contact contour 222 is indicated by a dash-dotted line in FIG. 13. The contact contour 222 may be fully encircling or may have one or more discontinuities.

Viewing FIG. 13 and 14 together, it is clear that the contacting arrangement 112 and the peripheral contact contour 222 have the following properties:

The contact contour 222 extends in a plane 224. Said plane is indicated by a dotted line in FIG. 14. The plane is depicted as a dotted line in said figure because the viewer's viewing direction is along the plane 224.

In a direction 226 orthogonal to the plane 224, the contacting arrangement 112 narrows toward the contact contour 222.

In the case of the protective element 110 illustrated in FIG. 15, the contacting arrangement 112 is oriented such that the contacting arrangement 112 narrows toward the contacting zone 120. In the example illustrated in FIG. 15, the contacting arrangement 112 narrows towards the contacting zone 120 because the contacting arrangement 112 is installed not in a lying configuration but in such a way as to stand on one edge, so to speak.

In the case of the protective element 110 illustrated in FIG. 15, too, the contacting arrangement 112 defines, on the protective element, a peripheral contact contour 222 as indicated in FIG. 13.

In the case of the protective element 110 illustrated in FIG. 15, too, the contact contour 222 extends in a plane 224. The plane is indicated by a dotted line in FIG. 15.

In a direction 226 orthogonal to the plane 224, the contacting arrangement 112 narrows toward the contact contour 222.

For example, as shown in FIG. 15, the contact contour 222 may be a contact contour 222 formed by a corner region 174 of the contacting arrangement 112. The corner region 174 may be a corner region 174 which extends along the contacting arrangement 112 in the main extent direction 142 of the contacting arrangement 112. The corner region 174 may be a rounded corner region 174. For example, it may be the case that the contacting arrangement 112 does not have a contacting protrusion 154, or the corner region 174 is not a corner region 174 of a contacting protrusion 154. The corner region 174 may advantageously be a corner region 174 of the main body 116 or of the plastics profile 148. It may be advantageous if the contacting arrangement 112 is tilted relative to the direction 226 which is orthogonal to the plane 224 or to the two planes 224.

It may be advantageous if, in the cross section of the contacting arrangement 112 and/or of the plastics profile 148, the corner region 174 projects out along the direction 226 which is orthogonal to the plane 224 or to the two planes 224. Alternatively or in addition, in the cross section 144, the corner region 174 may form an end of the contacting arrangement 112 along the direction 226 which is orthogonal to the plane 224 or to the two planes 224. The end may in particular be an end which, during the installation of the protective element 110 on a component 122, is capable of coming into contact first with a surface, facing toward the protective element 110, of the component 122.

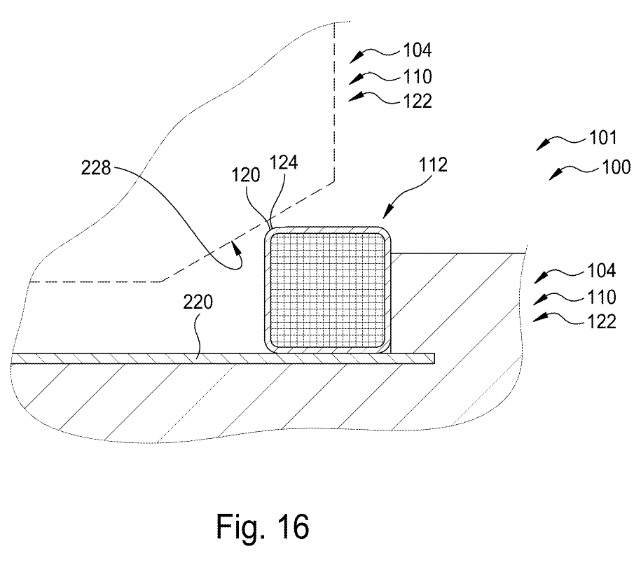

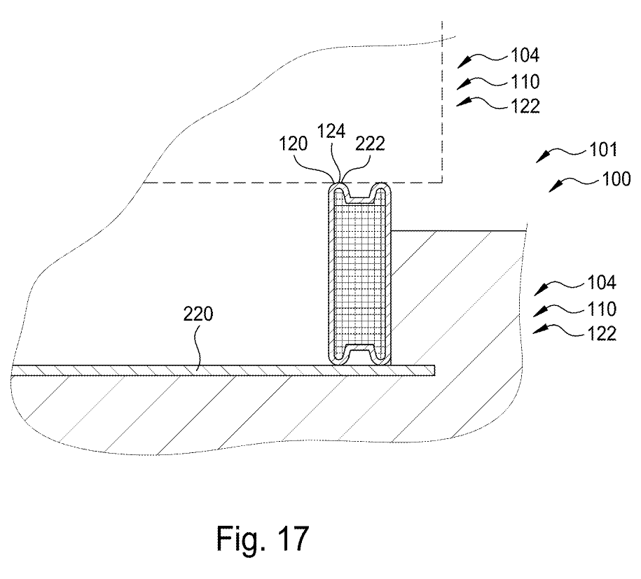

FIG. 16 and 17 are schematic illustrations of details of protective elements 101 for increasing electromagnetic compatibility. A complete protective arrangement is shown in a highly simplified schematic illustration in FIG. 1. The protective arrangement 101 illustrated in said figure is a housing 100.

The protective arrangements of which details are illustrated in FIG. 16 and 17 have two protective elements 110. In the case of each of the two protective arrangements illustrated in FIG. 16 and 17, the two protective elements 110 may fully or partially enclose an interior space 106 of the associated protective arrangement 101.

The two protective elements 110 are in electrical contact with one another via one of the contacting arrangements 112 described herein. As can be seen from FIG. 16 and 17, the electrical contact with at least one shielding layer 220 of one of the two protective elements 110 is established via the contacting arrangement 112.

The protective element 110, which is merely indicated by dashed lines in FIG. 16 and 17, has an inclined surface 228 in the embodiment illustrated in FIG. 16. If the protective element 110 illustrated at the bottom in FIG. 16 is moved toward the protective element 110 illustrated at the top in FIG. 16, electrical contact between the contacting arrangement 112 and the protective element 110 illustrated at the top by dashed lines is produced via the inclined surface 228 of the protective element 110 illustrated at the top.

In the two embodiments illustrated in FIGS. 16 and 17, one of the electrical contacts, in particular the electrical contact with the protective element 110 illustrated at the top by dashed lines in each case, is established via a contacting zone 120 described herein and/or via the peripheral contact contour 222 described herein.

In relation to the expensive contacting arrangements 112 which are shown for example in FIG. 2 (spring elements 114), the contacting arrangements 112 shown for example in FIG. 3 (main body 116 consisting of foamed plastics material 118) are inexpensive alternatives for producing an electromagnetic shielding action.

To be able to estimate the suitability of the contacting arrangements 112 for electromagnetic shielding, their electrical resistance in installed states was examined as follows:

Different contacting arrangements 112 (spring elements, according to FIG. 2, and contacting arrangements having main bodies consisting of foamed plastics material, according to FIG. 3) were each arranged in a test apparatus between planar metal surfaces in the presence of three different test temperatures of 22° C, 60° C and 85° C, wherein, in each case, the first contacting zone 124 came to lie against one of the two metal surfaces and the second contacting zone 126 came to lie against the other of the two metal surfaces. The metal surfaces were moved toward one another and fixed in place with a desired spacing of 4 mm, 5 mm, 6 mm or 7 mm, in the case of which the contacting arrangement 112 was compressed to different extents and was in electrical contact with the metal surfaces via the two contacting zones 124 and 126. The curve of the electrical resistance from metal surface to metal surface was subsequently recorded at regular intervals over a period of several hundred to over one thousand hours.

The following observations were made.

With the exception of the spring elements 114 according to FIG. 2, which exhibit a low contact resistance owing to a metallic spring action, the electrical resistance increased significantly following temperature-induced aging in the case of all examined contacting arrangements 112 having a main body 116 consisting of foamed plastics material 118.

The reason for this observation is considered to be a setting force loss of the foamed core materials used here. The setting force loss leads to a reduction in the contact stress in the metallic casing.

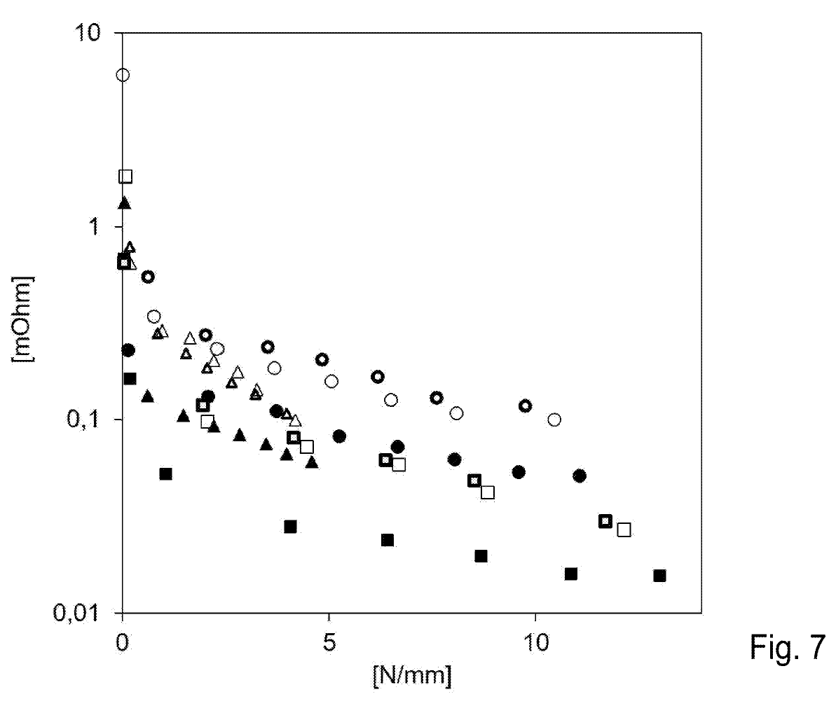

FIG. 7, 18, 19 and 20 illustrate results determined in the described test apparatus for different contacting arrangements 112 under similar conditions. In these four figures, for different line loads which were set in the test apparatus in each case (horizontal axis, unit: newtons per millimeter [N/mm]), a determined electrical resistance was plotted (vertical axis, unit: milliohms [mOhm]).

In FIG. 7, the triangles represent measurement data obtained with a contacting arrangement 112 according to FIG. 4 having a main body 116 consisting of ethylene propylene diene monomer (EPDM). The test was carried out a total of three times, for which purpose three contacting arrangements of identical construction were used (first test: solid triangles; second test: hollow triangles with thin border; third test: hollow triangles with thick border).

In FIG. 7, the circles represent measurement data obtained with a contacting arrangement 112 according to FIG. 5 having a main body 116 consisting of ethylene propylene diene monomer (EPDM). The test was carried out a total of three times, for which purpose three contacting arrangements of identical construction were used (first test: solid circles; second test: hollow circles with thin border; third test: hollow circles with thick border).

In FIG. 7, the squares represent measurement data obtained with a contacting arrangement 112 according to FIG. 6 having a main body 116 consisting of ethylene propylene diene monomer (EPDM). The test was carried out a total of three times, for which purpose three contacting arrangements of identical construction were used (first test: solid squares; second test: hollow squares with thin border; third test: hollow squares with thick border).

In all of the tests whose results were plotted in FIG. 7, the main body was partially encased with aluminum foil 134. The EPDM of the main body 116 was a solid elastomer material 166.

It was sought to achieve as low as possible an electrical resistance, in particular below 1 mOhm, which should be achieved with as low a line load as possible, as far below 2 N/mm as possible. For example, the electrical resistance as a function of the line load should be so low that log(y) < -x, where x stands for the line load units of N/mm, and y stands for the electrical resistance in units of mOhm, said electrical resistance being measurable from one metal surface to the other metal surface across the contacting arrangement situated between the metal surfaces.

FIG. 7 clearly shows that it was possible in some cases to fully achieve this aim with contacting arrangements 112 from FIG. 4, 5 and 6.

With the tested contacting arrangements 112 according to FIG. 4 to 6, the condition log(y) < -x was not met in the case of all tested line loads. Furthermore, the contacting arrangements 112 from FIG. 4, 5 and 6, with cross-sectional areas of approximately 10 mm x 4 mm, 10 mm x 7 mm and 10 mm x 10 mm, require a relatively large structural space and a relatively large amount of material.

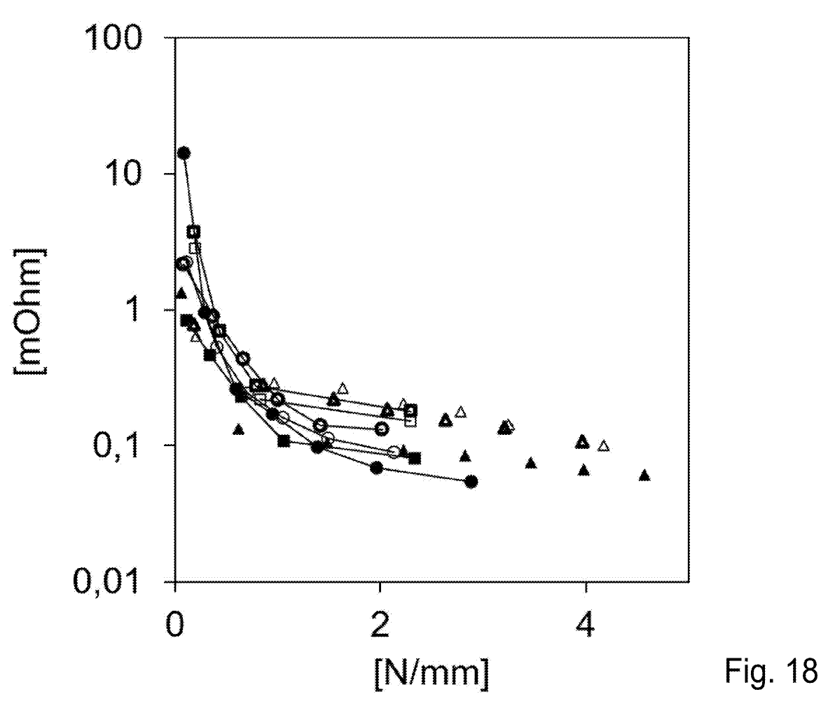

FIG. 18 shows results (electrical resistances at given line loads) determined with contacting arrangements 112 according to FIG. 4, 11 and 12 in the described test apparatus.

The contacting arrangement illustrated in FIG. 11 has a width of approximately 2.9 mm and a height of approximately 9.3 mm in the cross section shown. The contacting arrangement illustrated in FIG. 12 has a width of approximately 2.6 mm and a height of approximately 7.9 mm in the cross section shown.

As in FIG. 7, it is also the case in FIG. 18 that the triangles represent measurement data obtained with a contacting arrangement 112 according to FIG. 4 having a main body 116 consisting of ethylene propylene diene monomer (EPDM).

In FIG. 18, the circles represent measurement data obtained with a contacting arrangement 112 according to FIG. 11 (width 2.9 mm, height 9.3 mm) having a main body 116 consisting of an ethylene acrylate rubber (AEM), wherein the Shore hardness, measured in accordance with DIN ISO 7619-1, of the elastomer material was 60 Shore A. The main body was encased with aluminum foil. The test was carried out a total of three times, for which purpose three contacting arrangements of identical construction were used (first test: solid circles; second test: hollow circles with thin border; third test: hollow circles with thick border).

In FIG. 18, the squares represent measurement data obtained with a contacting arrangement 112 according to FIG. 12 (width 2.6 mm, height 7.9 mm) having a main body 116 consisting of an ethylene acrylate rubber (AEM), wherein the Shore hardness, measured in accordance with DIN ISO 7619-1, of the elastomer material was 60 Shore A. The main body was encased with aluminum foil. The test was carried out a total of three times, for which purpose three contacting arrangements of identical construction were used (first test: solid squares; second test: hollow squares with thin border; third test: hollow squares with thick border).

It can be seen from FIG. 18 that the electrical resistances in the presence of similar line loads in the case of the contacting arrangements according to FIG. 11 and 12 were substantially equally as low as, or lower than, the electrical resistances in the case of the contacting arrangements according to FIG. 4. This demonstrates that equally low or even lower electrical resistances can be achieved, with minimal outlay in terms of structural space and material, in particular if certain contacting arrangements according to the invention having a contacting protrusion are used. Surprisingly, particularly low electrical resistances were achieved despite a considerably smaller width of the contacting zones situated on the contacting protrusion.

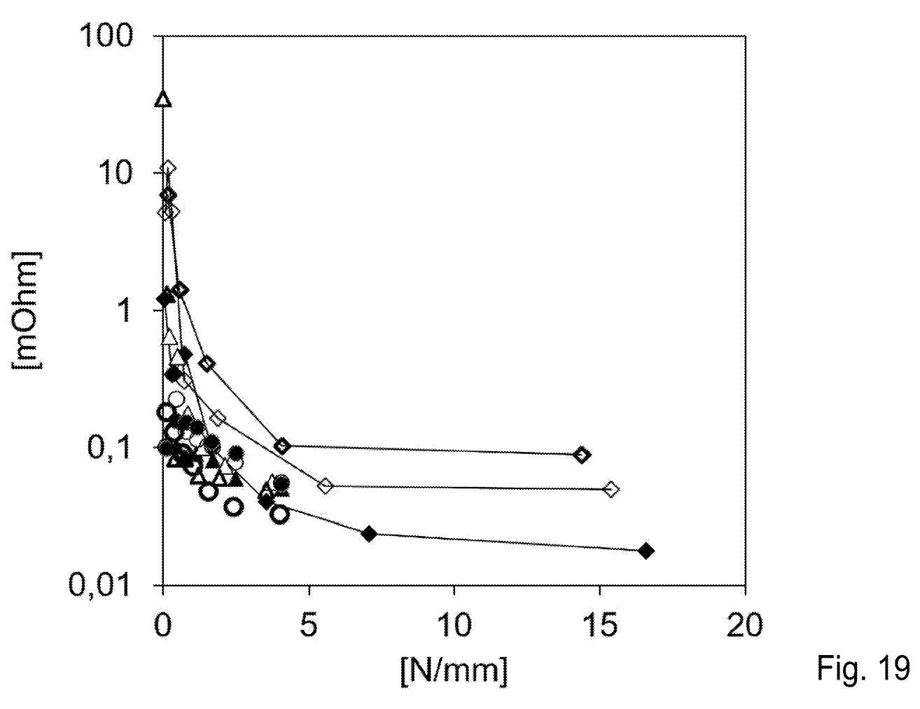

FIG. 19 shows electrical resistances at given line loads, determined with contacting arrangements 112 according to FIG. 9 in the described test apparatus (tilted squares).

The further results shown in FIG. 19 (triangles and circles) were obtained with contacting arrangements 112 according to FIG. 3. By contrast to FIG. 3, the contacting arrangements 112 had, as main body 116, silicone foam with an approximately rectangular cross section with dimensions of 10 mm x 15 mm.

It can be seen from FIG. 19 that it is for example also possible with contacting arrangements 112 according to the invention according to FIG. 9 to achieve very low electrical resistances from one of the metal surfaces across the particular contacting arrangement to the other metal surface in the case of low line loads. Contacting arrangements according to FIG. 9 offer a possibility for achieving this with a particularly small cross section, that is to say with little outlay on material. However, it is also true in the case of a rectangular cross section of the silicone foams that setting force losses, and associated increases in electrical resistances, are to be expected with temperature-induced aging.

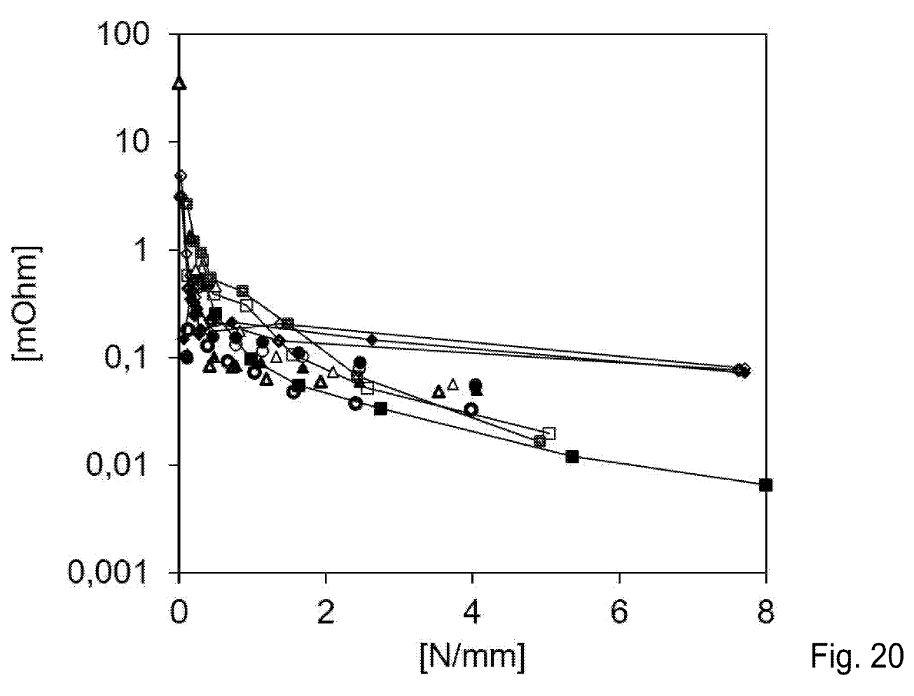

FIG. 20 also shows electrical resistances at given line loads, determined with contacting arrangements 112 according to FIG. 8 (squares) and 10 (tilted squares) in the described test apparatus.

The further results which are also illustrated in FIG. 20 by means of triangles and circles correspond to the further results from FIG. 19. They are also shown in FIG. 20 in particular for comparison purposes.

It can be seen from FIG. 20 that it is for example also possible with contacting arrangements 112 according to the invention according to FIG. 8 and 10 to achieve very low electrical resistances from one of the metal surfaces across the particular contacting arrangement to the other metal surface in the case of low line loads. Contacting arrangements according to FIG. 8 and 10 also offer possibilities for achieving this with little outlay on material.

The contacting arrangements 112 according to FIG. 19 and 20 can be produced in particularly material-saving fashion owing to their design, for example owing to the associated cavities and/or the profiles installed therein.

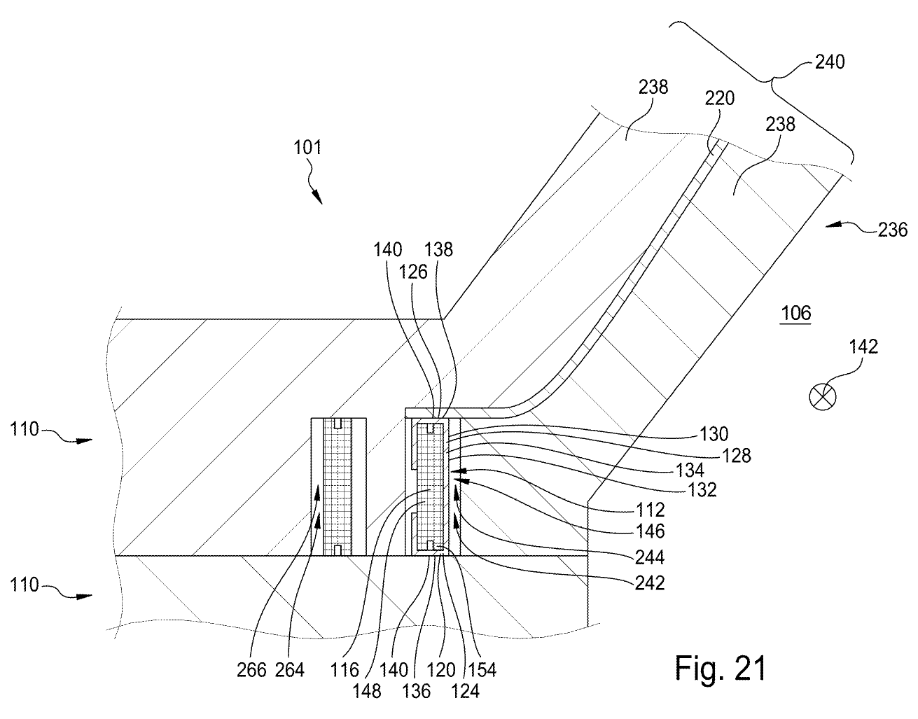

FIG. 21, 22 and 23 each show details of protective arrangements 101 for increasing electromagnetic compatibility. The contacting arrangements 101 shown each have two protective elements 110. One of the two protective elements 110 is a protective element 110 according to the invention which has a shielding layer 220 for protecting against electrical, magnetic or electromagnetic fields. In the protective arrangements 101 according to FIG. 21, 22 and 23, the two protective elements 110 are in electrical contact with one another via a contacting arrangement 112 according to the invention.

The contacting arrangements 112 shown in FIG. 21, 22 and 23 each have a contacting protrusion 154. The contacting arrangements 112 each have a contacting zone 120 on the contacting protrusion 154. In each case, the contacting zone 120 is a first contacting zone 124, and the contacting arrangement 112 has a second contacting zone 126, wherein the first contacting zone 124 is electrically conductively connected to the second contacting zone 126. There are similarities to the contacting arrangements 112 in FIG. 11 and 12, and therefore numerous consistent or corresponding features will not be described again with regard to FIG. 21, 22 and 23, and some reference signs have also been omitted in FIG. 21, 22 and 23.

The first contacting zone 124 and the second contacting zone 126 are connected by means of an electrically conductive material 128. The electrically conductive material 128 is a metallic material, which may for example contain aluminum.

The electrically conductive material 128 may for example be or have a metallic foil, a metallic lattice, a metallic mesh or a metallic fabric, in particular an aluminum foil 134, an aluminum lattice, an aluminum mesh or an aluminum fabric.

For example, the electrically conductive material 128 may be a sheet material 130, in particular a sheet aluminum material 132, for example an aluminum foil 134.

Each contacting arrangement 112 has a first surface region 136 and a second surface region 138. The first contacting zone 124 is formed on the first surface region 136, and the second contacting zone 126 is formed on the second surface region 138.

The first surface region 136 and the second surface region 138 are mutually spaced surface portions 140 of the electrically conductive material 128.

In the case of the contacting arrangement 112 shown in FIG. 21, in a cross section 144 oriented orthogonally to the main extent direction 142 of the contacting arrangement 112, the electrically conductive material 128 extends almost all the way around the main body 116 and almost all the way around the plastics profile 148.

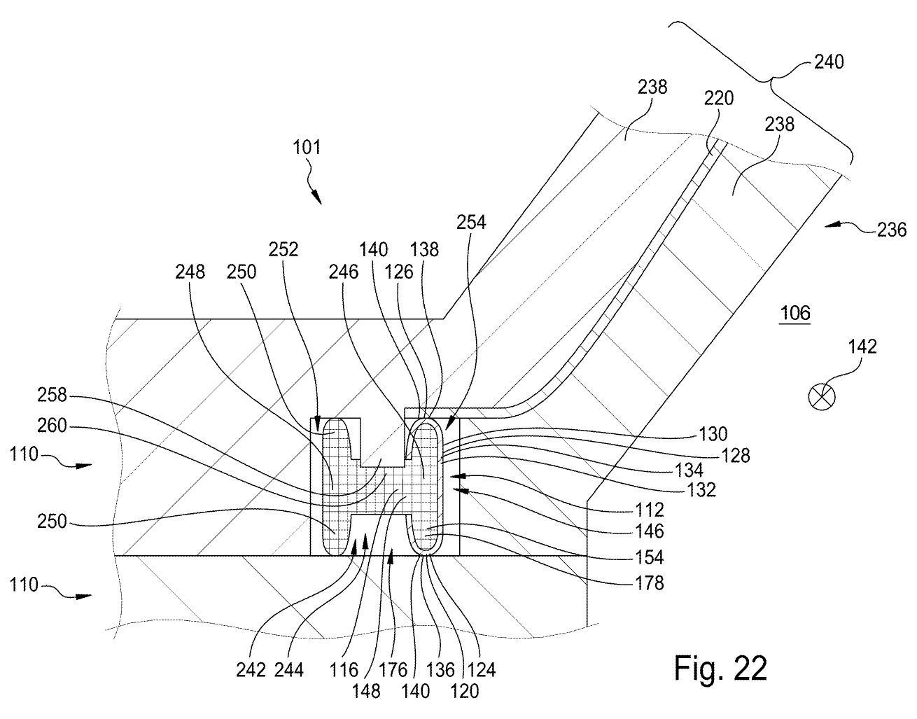

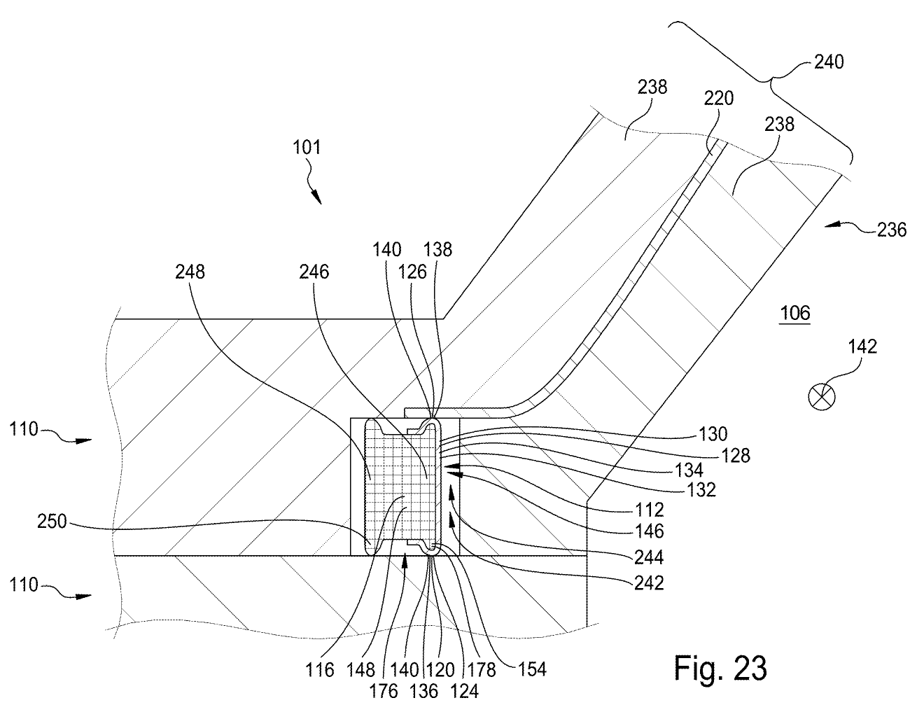

In the case of each of the contacting arrangements 112 shown in FIG. 22 and 23, in a cross section 144 oriented orthogonally to the main extent direction 142 of the contacting arrangement 112, the electrically conductive material 128 extends part of the way around the main body 116 and part of the way around the plastics profile 148.

The protective elements 110 according to the invention shown in FIG. 21, 22 and 23 each have two barrier elements 238, namely a barrier element 238 and a further barrier element 238. The shielding layer 220 extends between the two barrier elements 238 at least in certain portions. The shielding layer 220 may be arranged on the barrier elements 238. The shielding layer 220 may optionally form, for example, a layer composite 240 together with the barrier elements 238.

Each of the protective elements 110 shown in FIG. 21, 22 and 23 has a side wall 236 and an interior space 106. The interior space 106 is fully or partially surrounded by the side wall 236, which can be merely surmised from each of the illustrated details of the pot-shaped and/or trough-shaped protective elements 110.

Thus, in each case, the side wall 236 is formed entirely or partially by a barrier element 238.

The protective elements 110 according to the invention shown in FIG. 21, 22 and 23 each have a contacting arrangement receiving zone 242 in which the associated contacting arrangement 112 is arranged. In each of the three examples shown, the contacting arrangement receiving zone 242 has a contacting arrangement receiving depression 244 in which the associated contacting arrangement 112 is partially received. The contacting arrangement receiving zone 242 is delimited by the two barrier elements 238. The shielding layer 220 extends into the contacting arrangement receiving zone 242. The contacting arrangement 112 is in electrical contact with the shielding layer 220 in the contacting arrangement receiving zone 242.

The contacting arrangements 112 shown in FIG. 21, 22 and 23 are EMC seal arrangements 146. For example, they may impart a fluid-sealing action between two protective elements 110 or components 122 and provide shielding against electromagnetic radiation.

The two contacting arrangements 112 shown in FIG. 22 and 23 have a contacting portion 246 and a sealing portion 248 as seen in the cross sections 144 shown here, said cross sections being oriented orthogonally to the main extent direction 142 of the particular contacting arrangement 112. The contacting portion 246 has the contacting protrusion 154. The contacting protrusion 154 is a component contacting protrusion 178 present in the contacting portion 246 on a component contacting side 176 of the contacting arrangement 112. The sealing portion 246 has a sealing protrusion 250. The sealing protrusion 250 is a sealing protrusion 250 present in the sealing portion 248 on the component contacting side 176 of the contacting arrangement 112.

In a cross section oriented orthogonally to the main extent direction 142 of each contacting arrangement 112, the electrically conductive material 128 extends from the first contacting zone 124 to the second contacting zone 126.

The contacting protrusion 154 and the sealing protrusion 250 are considerably larger in the case of the contacting arrangement 112 shown in FIG. 22 than in the case of the contacting arrangement 112 shown in FIG. 23.

It can be clearly seen from FIG. 22 and 23 that the contacting arrangement narrows toward the contacting zones 120, 124, 126. The contacting protrusions are each wider at a base of the particular contacting protrusion, in particular in the cross sections shown, than at their ends, at which the associated contacting zone 124 or 126 is situated.

The contacting arrangement receiving zone 242 shown in FIG. 22 has a sealing compartment 252 and a contacting compartment 254. The second contacting zone 126 is in electrical contact with the shielding layer 220 in the contacting compartment 254. The sealing portion 246 has two mutually opposite sealing protrusions 250, wherein one of the sealing protrusions 250 projects into the sealing compartment 252.

An intermediate support portion 258 projects into the contacting arrangement receiving zone 242 and separates the sealing compartment 252 from the contacting compartment 254. An intermediate portion 260 of the contacting arrangement 112 is arranged on the intermediate support portion 258.

The protective element 110 according to the invention shown in FIG. 21 has not only the contacting arrangement receiving zone 242 but also a sealing element receiving zone 264 in which a sealing element 262 is arranged. The sealing element receiving zone 264 has a sealing element receiving depression 266 in which the sealing element 262 can be entirely or partially received. The sealing element receiving zone 264 extends substantially parallel to the contacting arrangement receiving zone 242.

### LIST OF REFERENCE SIGNS

100 Housing
101 Protective arrangement
102 Source
104 Delimiting element
106 Interior space
108 Exterior space
110 Protective element
112 Contacting arrangement
114 Spring element
116 Main body
118 Plastics material
120 Contacting zone
122 Component
124 First contacting zone
126 Second contacting zone
128 Electrically conductive material
130 Sheet material
132 Sheet aluminum material
134 Aluminum foil
136 First surface region
138 Second surface region
140 Surface portion
142 Main extent direction
144 Cross section
146 EMC seal arrangement
148 Plastics profile
150 Elastic plastics profile
152 Elastomer profile
154 Contacting protrusion
156 Apical surface region
158 Basal surface region
160 Elastomer material
162 Support protrusion
164 Solid plastics material
166 Solid elastomer material
168 Elevation
170 Ridge
172 Plastics profile portion
174 Corner region
176 Component contacting side
178 Component contacting protrusion
180 Further component contacting protrusion
182 Component contacting zone
184 Contacting unit
186 Further contacting zone
188 Further component contacting zone
190 Metal profile
192 Contacting lip
194 Portion
196 Cavity
198 U profile
200 First direction
202 Extent
204 Second direction
206 Extent
208 Attachment surface
210 Contacting surface
212 Installation direction
214 Aluminum U profiles
216 Intermediate contact zone
218 Frictional contact zone
220 Shielding layer
222 Contact contour
224 Plane
226 Direction
228 Inclined surface
230 Pressure-exerting device
232 Pressure-exerting spring element
234 Intermediate contact-promoting element
236 Side wall
238 Barrier element
240 Layer composite
242 Contacting arrangement receiving zone
244 Contacting arrangement receiving depression
246 Contacting portion
248 Sealing portion
250 Sealing protrusion
252 Sealing compartment
254 Contacting compartment
258 Intermediate support portion
260 Intermediate portion
262 Sealing element
264 Sealing element receiving zone
266 Sealing element receiving depression

1. A contacting arrangement for electrically contacting a protective element for increasing electromagnetic compatibility,
wherein the contacting arrangement has a contacting zone.

2. The contacting arrangement according to claim 1, wherein
the contacting arrangement has a contacting protrusion, and
the contacting arrangement has the contacting zone on the contacting protrusion.

3. The contacting arrangement according to claim 2, wherein
the contacting zone is a first contacting zone,
the contacting arrangement has a second contacting zone, and
the first contacting zone is electrically conductively connected to the second contacting zone.

4. The contacting arrangement according to claim 2, wherein
the contacting arrangement has a main body,
and/or
the contacting arrangement has a plastics material,
and/or
the contacting arrangement has a main body and a plastics material, and wherein the plastics material extends into the main body and into the contacting protrusion and/or the main body and the contacting protrusion are constructed entirely or partially from the plastics material,
and/or
the contacting protrusion projects out of the main body,
and/or
the plastics material is an elastomer material,
and/or
the contacting arrangement has a plastics profile, and wherein, the plastics profile is an elastic plastics profile and/or an elastomer profile and/or in a cross section of the plastics profile, the plastics profile extends into the contacting protrusion.

5. The contacting arrangement according to claim 4, wherein
the plastics material, the elastomer material and/or the plastics profile is not foamed, and/or
the plastics material, the elastomer material and/or the plastics profile is a solid plastics material, a solid elastomer material and/or a plastics profile consisting of solid plastics material or solid elastomer material.

6. The contacting arrangement according to claim 4, wherein
the contacting protrusion is an elevation which projects out of the main body and/or a ridge projecting out of the main body,
or
the contacting protrusion is an elevation which has a ridge projecting out of the main body,
and/or
the contacting protrusion is an elevation which, in the cross section, projects out of a plastics profile portion of the plastics profile and is a ridge projecting out of the plastics profile portion or have a ridge projecting out of the plastics profile portion, and wherein the elevation and/or the ridge may extend along the plastics profile in a main extent direction of the contacting arrangement.

7. The contacting arrangement according to claim 6, wherein
the elevation and/or the ridge extend along the main body in a main extent direction of the contacting arrangement.

8. The contacting arrangement according to claim 2, wherein
the contacting protrusion is a component contacting protrusion present on a component contacting side of the contacting arrangement, and
the contacting arrangement has a further component contacting protrusion on the component contacting side.

9. The contacting arrangement according to claim 8, wherein
the contacting zone is a component contacting zone or the first contacting zone is a first component contacting zone, and
the contacting arrangement has the component contacting zone or the first component contacting zone on the component contacting protrusion,
the contacting arrangement has a further contacting zone, the further contacting zone is a further component contacting zone, and the contacting arrangement has the further component contacting zone on the further component contacting protrusion.

10. The contacting arrangement according to claim 8, wherein
the component contacting protrusion and the further component contacting protrusion are spaced from one another on the component contacting side at least in a cross section of the contacting arrangement oriented orthogonally to the main extent direction of the contacting arrangement.

11. The contacting arrangement according to claim 10, wherein
the component contacting protrusion and the further component contacting protrusion are elevations which project out of the main body,
and/or
the component contacting protrusion and the further component contacting protrusion are elevations which, in the cross section, project out of a plastics profile portion of the plastics profile, or project out of a plastics profile portion of the plastics profile on the component contacting side of the plastics profile portion,
and/or
the component contacting protrusion and the further component contacting protrusion are elevations which are ridges projecting out of the plastics profile portion or have ridges projecting out of the plastics profile portion.

12. The contacting arrangement according to claim 11, wherein
the elevations project out of the main body on the component contacting side of the main body, and
the elevations are ridges projecting out of the main body or have ridges projecting out of the main body.

13. The contacting arrangement according to claim 11, wherein
the elevations and/or ridges extend along the main body in a main extent direction of the contacting arrangement.

14. The contacting arrangement according to claim 4, wherein
the contacting protrusion is a contacting lip which projects out of the main body and which is inclined and/or bent transversely to a main extent direction of the contacting arrangement,
and/or
the contacting protrusion s a contacting lip which extends along the main body in a main extent direction of the contacting arrangement,
and/or
the contacting protrusion is a contacting lip which projects out of a plastics profile portion of the plastics profile, and wherein, in the cross section of the plastics profile, the plastics profile extends into the contacting lip and the contacting lip is oriented obliquely in the cross section,
and/or
the contacting protrusion is a contacting lip which extends along the plastics profile portion in a main extent direction of the contacting arrangement.

15. The contacting arrangement according to claim 4, wherein
the contacting protrusion extends from the main body, through a portion of the contacting protrusion which is spaced from the main body, to the main body, and wherein the main body and the contacting protrusion enclose a cavity,
and/or
the contacting protrusion extends from a plastics profile portion of the plastics profile, through a portion of the contacting protrusion which is spaced from the plastics profile portion, to the plastics profile portion, and wherein the plastics profile portion and the contacting protrusion enclose a cavity.

16. The contacting arrangement according to claim 1, wherein
the contacting arrangement is an EMC seal arrangement.
and/or
the contacting zone can be placed in electrical contact with a component against which the contacting arrangement can come to lie.

17. A protective element for increasing electromagnetic compatibility, wherein
the protective element has the following:
a shielding layer for protecting against electrical, magnetic or electromagnetic fields, and
the contacting arrangement according to claim 1 which is in electrical contact with the shielding layer.

18. The protective element according to claim 17, wherein
the contacting arrangement is arranged and/or oriented such that the contacting arrangement narrows toward the contacting zone,
and/or
the contacting arrangement defines, on the protective element, a peripheral contact contour for producing electrical contact, and wherein the contact contour may be fully encircling or may have one or more discontinuities.

19. The protective element according to claim 18, wherein
the contacting arrangement and the peripheral contact contour have the following properties:
the contact contour extends in a plane, or, if the contact contour does not extend in a plane, the profile of the contact contour can be described by two mutually parallel planes which are spaced to the least possible extent, and wherein the contact contour extends entirely between the two planes,
and
the contacting arrangement narrows toward the contact contour in a direction orthogonal to the plane or to the two planes.

20. A protective arrangement for increasing electromagnetic compatibility, wherein the protective arrangement has at least two protective elements which fully or partially enclose an interior space of the protective arrangement, wherein
at least one of the at least two protective elements is a protective element according to claim 17,
and/or
the at least two protective elements are in electrical contact with one another via said contacting arrangement, and
an electrical contact with at least one shielding layer of one of the at least two protective elements is established via the contacting arrangement,
or
an electrical contact between a shielding layer of one of the at least two protective elements and a shielding layer of another of the at least two protective elements is established via the contacting arrangement.

21. The protective arrangement according to claim 20, wherein
at least one of at least two electrical contacts between the contacting arrangement and at least one of the at least two protective elements is established via an inclined surface of the at least one of the at least two protective elements,
and/or
at least one of at least two electrical contacts between the contacting arrangement and at least one of the at least two protective elements is established via the contacting zone,
and/or
at least one of at least two electrical contacts between the contacting arrangement and at least one of the at least two protective elements is established via the peripheral contact contour.
